(19) United States
(12) Patent Application Publication
(10) Pub. No.: US 2024/0321829 A1
(43) Pub. Date: Sep. 26, 2024

(54) SEMICONDUCTOR STORAGE DEVICE AND SEMICONDUCTOR DEVICE

(71) Applicant: Kioxia Corporation, Tokyo (JP)

(72) Inventor: Nobuyuki MOMO, Yokohama Kanagawa (JP)

(21) Appl. No.: 18/589,300

(22) Filed: Feb. 27, 2024

(30) Foreign Application Priority Data
Mar. 20, 2023 (JP) 2023-043868

(51) Int. Cl. H01L 25/065; H01L 23/00; H10B 41/10; H10B 41/35; H10B 43/10; H10B 43/35

(52) U.S. Cl. CPC H01L 25/0657; H01L 24/08; H01L 24/80; H10B 41/10; H10B 41/35; H10B 43/10; H10B 43/35; H01L 2224/08145; H01L 2224/80894; H01L 2924/14511

(57) ABSTRACT

A semiconductor storage device includes first and second chips. The first chip includes a semiconductor substrate having first and second surfaces intersecting a first direction, and a plurality of transistors provided on the first surface of the semiconductor substrate. The plurality of transistors include first and second transistors adjacent to each other in a second direction intersecting the first direction. The semiconductor substrate includes a first insulating member provided between the first transistor and the second transistor and extending in the first direction from the first surface of the semiconductor substrate to a first position between the first surface and the second surface of the semiconductor substrate, and a second insulating member provided at a position overlapping the first insulating member when viewed in the first direction and extending in the first direction from the second surface of the semiconductor substrate to the first position of the semiconductor substrate.

### CROSS-REFERENCE TO RELATED APPLICATION(S)

This application is based upon and claims the benefit of priority from Japanese Patent Application No. 2023-043868, filed Mar. 20, 2023, the entire contents of which are incorporated herein by reference.

### FIELD

Embodiments described herein relate generally to a semiconductor storage device and a semiconductor device.

### BACKGROUND

A semiconductor storage device includes a substrate, a plurality of conductive layers, a semiconductor layer, and a gate insulating layer. The plurality of conductive layers are stacked in a direction intersecting a front surface of the substrate. The semiconductor layer faces the plurality of conductive layers. The gate insulating layer is provided between the conductive layer and the semiconductor layer. The gate insulating layer includes a storage layer capable of storing data, e.g., an insulating charge storage layer such as silicon nitride (SiN) or a conductive charge storage layer such as a floating gate.

### DESCRIPTION OF THE DRAWINGS

FIG. 1 is a schematic block diagram showing a configuration of a memory die according to a first embodiment.

FIG. 2 is a schematic circuit diagram showing a configuration of a part of the memory die.

FIG. 3 is a schematic circuit diagram showing a configuration of a voltage generation circuit, a driver circuit, and a row decoder.

FIG. 4 is a schematic circuit diagram showing a configuration of a row control circuit and a block decoder.

FIG. 5 is an exploded perspective view schematically showing a configuration example of a semiconductor storage device according to the first embodiment.

FIG. 6 is a schematic top view showing a configuration example of a chip.

FIGS. 7-8 are schematic cross-sectional views showing a configuration of a part of the memory die.

FIG. 9 is a schematic top view showing a configuration of a part of the chip.

FIG. 10 is a schematic cross-sectional view showing a configuration of a part of the chip.

FIG. 11 is a schematic plan view showing a configuration example of a hook up region.

FIG. 12 is a schematic bottom view showing a configuration example of a chip.

FIGS. 13-15 are schematic bottom views showing a configuration of a part in a row control circuit region.

FIGS. 16-18 are schematic cross-sectional views showing an example of a configuration of a part in the row control circuit region.

FIGS. 19-26 are schematic cross-sectional views illustrating steps of a method of manufacturing a CMOS portion of the chip.

FIGS. 27-28 are schematic cross-sectional views illustrating a method of manufacturing bonding wafers.

FIGS. 29-35 are schematic cross-sectional views illustrating a method of manufacturing a semiconductor substrate portion of the chip.

FIGS. 36-37 are schematic cross-sectional views showing a configuration of a part of a memory die according to a comparative example.

FIGS. 38-40 are schematic cross-sectional views showing a configuration of a part of a semiconductor storage device according to a second embodiment.

FIG. 41 is a schematic bottom view showing a configuration of a part of a semiconductor storage device according to a third embodiment.

FIGS. 42-43 are schematic cross-sectional views showing a configuration of a part of the semiconductor storage device according to the third embodiment.

FIG. 44 is a schematic bottom view showing a configuration of a part of a semiconductor storage device according to a fourth embodiment.

FIGS. 45-46 are schematic cross-sectional views showing a configuration of a part of the semiconductor storage device according to the fourth embodiment.

FIGS. 47-48 are schematic cross-sectional views showing a configuration of a part of the semiconductor storage device according to the fourth embodiment.

FIG. 49 is a schematic cross-sectional view illustrating the method of manufacturing the semiconductor substrate portion of the chip according to other embodiments.

### DETAILED DESCRIPTION

Embodiments provide a semiconductor storage device capable of high integration.

In general, according to one embodiment, a semiconductor storage device includes a first chip and a second chip bonded to each other. The first chip includes a semiconductor substrate having a first surface and a second surface intersecting a first direction, a plurality of transistors provided on the first surface of the semiconductor substrate, a plurality of first contacts extending in the first direction and connected to the plurality of transistors, and a plurality of first bonding electrodes electrically connected to the plurality of transistors via the plurality of first contacts. The second chip includes a plurality of first conductive layers arranged in the first direction, a semiconductor column extending in the first direction and facing the plurality of first conductive layers, a plurality of second contacts extending in the first direction and connected to the plurality of first conductive layers, and a plurality of second bonding electrodes connected to the plurality of first conductive layers via the plurality of second contacts. In the first chip and the second chip, the plurality of first bonding electrodes are bonded to the plurality of second bonding electrodes. The plurality of transistors include a first transistor and a second transistor adjacent to each other in a second direction intersecting the first direction.

The semiconductor substrate includes a first insulating member provided between the first transistor and the second transistor and extending in the first direction from the first surface of the semiconductor substrate to a first position between the first surface and the second surface of the semiconductor substrate, and a second insulating member provided at a position overlapping the first insulating member when viewed in the first direction and extending in the first direction from the second surface of the semiconductor substrate to the first position of the semiconductor substrate. A width of the second insulating member in the second direction at the second surface is larger than a width of the first insulating member in the second direction at the first surface.

Next, the semiconductor storage device according to the embodiment will be described in detail with reference to the drawings. The following embodiments are only examples, and are not intended to limit the scope of the present disclosure. Further, the following drawings are schematic, and some configurations and the like may be omitted for convenience of explanation. Moreover, the parts which are common to a plurality of embodiments may be given the same reference labels, and the description thereof may be omitted.

The term “semiconductor storage device” used in the present specification may mean a memory die, or mean a memory system including a controller die such as a memory chip, a memory card, or a solid state drive (SSD). The term “semiconductor storage device” may mean a configuration including a host computer such as a smartphone, a tablet terminal, and a personal computer.

In the present specification, when a first configuration is said to be “electrically connected” to a second configuration, the first configuration may be directly connected to the second configuration, or the first configuration may be connected to the second configuration via wiring, a semiconductor member, a transistor, or the like. For example, when three transistors are connected in series, a first transistor is “electrically connected” to a third transistor even though a second transistor is in an OFF state.

In the present specification, a case where the first configuration is said to be “connected between” the second configuration and a third configuration may mean that the first configuration, the second configuration, and the third configuration are connected in series and the second configuration is connected to the third configuration via the first configuration.

In the present specification, a case where a circuit or the like is said to cause two wirings and the like to be “electrically connected” may mean, for example, that the circuit or the like includes a transistor and the like, the transistor and the like are provided on a current path between the two wirings, and the transistor and the like are in an ON state.

In the present specification, a predetermined direction parallel to an upper surface of a substrate is referred to as an X direction, a direction which is parallel to the upper surface of the substrate and is perpendicular to the X direction is referred to as a Y direction, and a direction perpendicular to the upper surface of the substrate is referred to as a Z direction.

In the present specification, a direction along a predetermined surface is referred to as a first direction, a direction intersecting the first direction along the predetermined surface is referred to as a second direction, and a direction intersecting the predetermined surface is referred to as a third direction. The first direction, the second direction, and the third direction may or may not correspond to any of the X direction, the Y direction, and the Z direction.

In addition, in the present specification, expressions such as “upper” and “lower” are based on an external pad electrode that can be connected to a bonding wire. For example, in the memory die MD, a direction approaching the external pad electrode in the Z direction is referred to as an upper direction, and a direction away from the external pad electrode along the Z direction is referred to as a lower direction. Further, when referring to a lower surface or a lower end of a certain component, it means a surface or an end portion of this component that is on a side farther from the external pad electrode of this component. When referring to an upper surface or an upper end, it means a surface or an end portion of this component that is on a side closer to the external pad electrode. A surface intersecting the X direction or the Y direction is referred to as a side surface or the like.

Further, in the present specification, when referring to a “width”, a “length”, a “thickness”, or the like in a predetermined direction for a component, a member, and the like, this means the width, the length, the thickness, or the like in a cross section or the like observed by scanning electron microscopy (SEM), transmission electron microscopy (TEM), or the like.

### First Embodiment

### Circuit Configuration of Memory Die MD

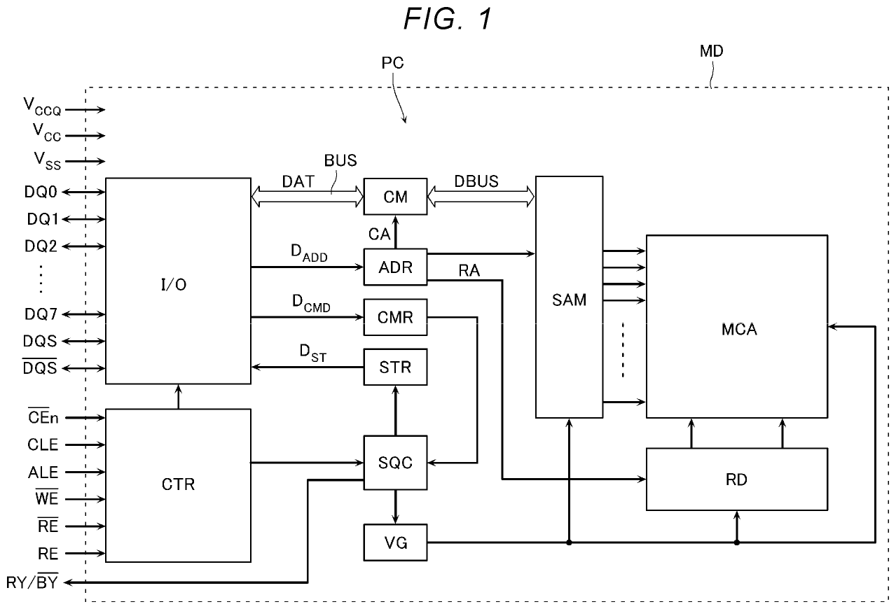

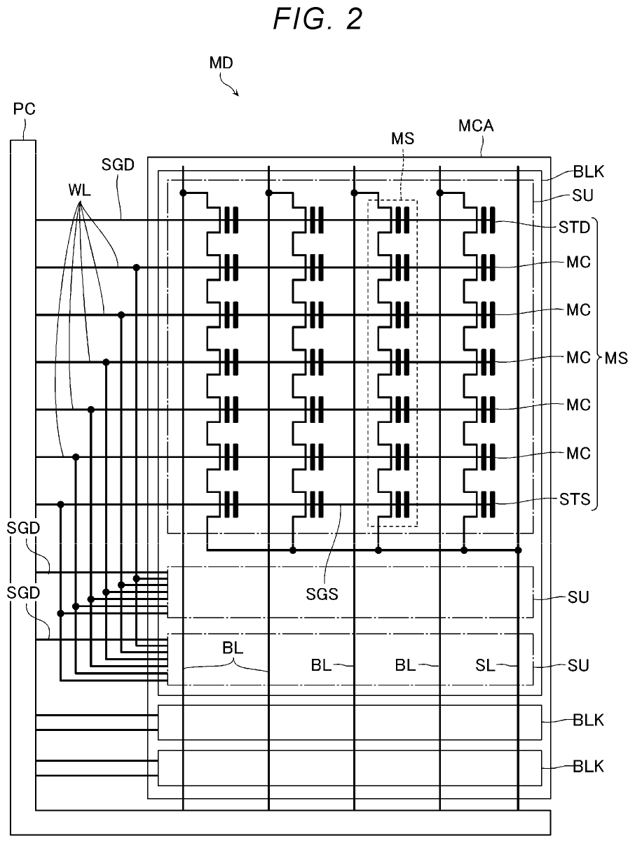

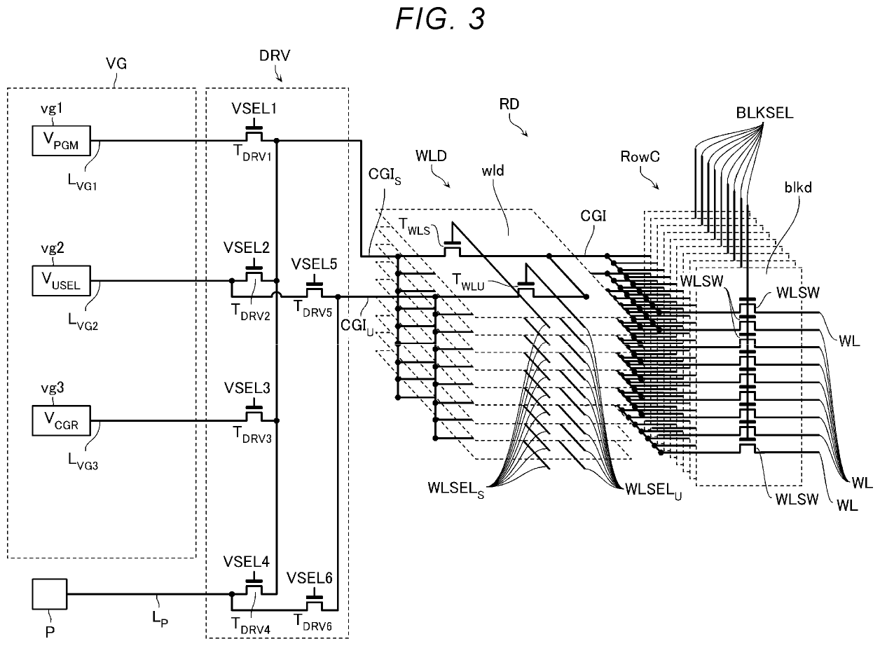

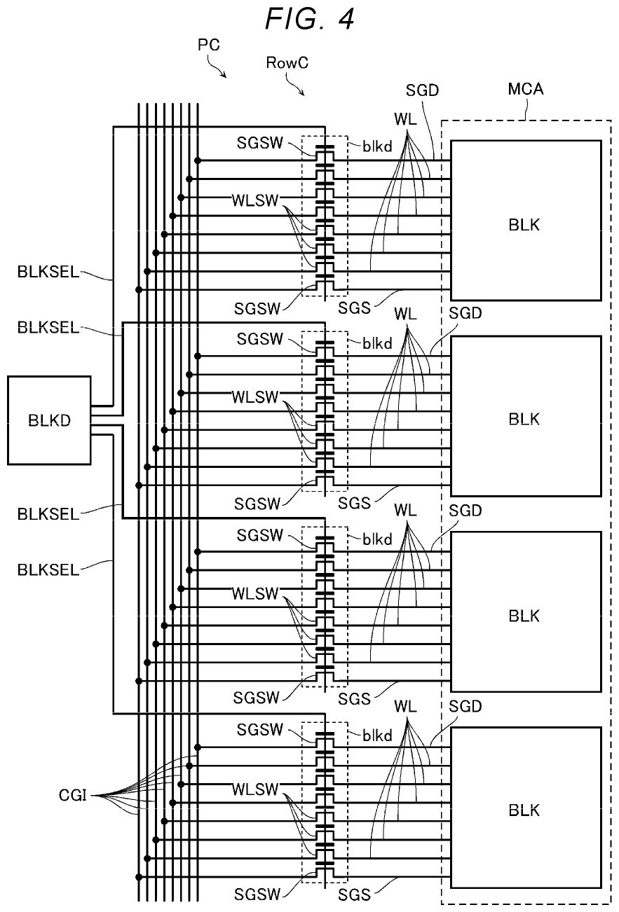

FIG. 1 is a schematic block diagram showing a configuration of a memory die MD according to a first embodiment. FIG. 2 is a schematic circuit diagram showing a configuration of a part of the memory die MD. FIG. 3 is a schematic circuit diagram showing a configuration of a voltage generation circuit VG, a driver circuit DRV, and a row decoder RD. FIG. 4 is a schematic circuit diagram showing a configuration of a row control circuit RowC and a block decoder BLKD.

FIG. 1 shows a plurality of control terminals and the like. The plurality of control terminals may be represented as control terminals corresponding to a high active signal (positive logic signal). The plurality of control terminals may be represented as control terminals corresponding to a low active signal (negative logic signal). The plurality of control terminals may be represented as control terminals corresponding to both the high active signal and the low active signal. In FIG. 1, the reference label of the control terminal corresponding to the low active signal includes an overline. In the present specification, the reference sign of the control terminal corresponding to the low active signal includes a slash (“/”). The illustration of FIG. 1 is an example, and the specific form may be adjusted as appropriate. For example, a part or all of high active signals may be set to the low active signals, or a part or all of low active signals may be set to the high active signals.

As shown in FIG. 1, the memory die MD includes a memory cell array MCA and a peripheral circuit PC. The peripheral circuit PC includes a voltage generation circuit VG, a row decoder RD, a sense amplifier module SAM, and a sequencer SQC. The peripheral circuit PC further includes a cache memory CM, an address register ADR, a command register CMR, and a status register STR. The peripheral circuit PC further includes an input/output control circuit I/O and a logic circuit CTR.

### Circuit Configuration of Memory Cell Array MCA

As shown in FIG. 2, the memory cell array MCA includes a plurality of memory blocks BLK. Each of the plurality of memory blocks BLK includes a plurality of string units SU. Each of the plurality of string units SU includes a plurality of memory strings MS. One end of each of the plurality of memory strings MS is connected to the peripheral circuit PC via a bit line BL. The other end of each of the plurality of memory strings MS is connected to the peripheral circuit PC via a common source line SL.

The memory string MS includes a drain-side select transistor STD, a plurality of memory cells MC (also referred to as memory transistors), and a source-side select transistor STS. The drain-side select transistor STD, the plurality of memory cells MC, and the source-side select transistor STS are connected in series between the bit line BL and the source line SL. Hereinafter, the drain-side select transistor STD and the source-side select transistor STS may be simply referred to as a select transistor (STD, STS).

The memory cell MC is a field effect transistor. The memory cell MC includes a semiconductor layer, a gate insulating film, and a gate electrode. The semiconductor layer functions as a channel region. The gate insulating film includes a charge storage film. A threshold voltage of the memory cell MC is changed according to a charge quantity in the charge storage film. The memory cell MC stores data of one bit or a plurality of bits. Word lines WL are connected to gate electrodes of the plurality of memory cells MC corresponding to one memory string MS. Each of these word lines WL is commonly connected to all the memory strings MS in one memory block BLK.

The select transistors (STD, STS) are field effect transistors. Each of the select transistors (STD, STS) includes a semiconductor layer, a gate insulating film, and a gate electrode. The semiconductor layer functions as a channel region. The gate insulating film may include a charge storage layer. A drain-side select gate line SGD is connected to the gate electrode of the drain-side select transistor STD, and a source-side select gate line SGS is connected to the gate electrode of the source-side select transistor STS. One drain-side select gate line SGD is commonly connected to all of the memory strings MS in one string unit SU. One source-side select gate line SGS is commonly connected to all of the memory strings MS in one memory block BLK. Each of the drain-side select gate line SGD and the source-side select gate line SGS may be referred to as a select gate line SG.

### Circuit Configuration of Voltage Generation Circuit VG

The voltage generation circuit VG (FIG. 1) includes a plurality of voltage generation units vg1 to vg3, for example, as shown in FIG. 3. The voltage generation units vg1 to vg3 generate voltages of predetermined magnitudes in a read operation, a write operation, and an erasing operation, and output the generated voltages via voltage supply lines L_{VG}. For example, the voltage generation unit vg1 outputs a program voltage in the write operation. In addition, the voltage generation unit vg2 outputs a read pass voltage in the read operation. In addition, the voltage generation unit vg2 outputs a write pass voltage in the write operation. In addition, the voltage generation unit vg3 outputs a read voltage in the read operation. In addition, the voltage generation unit vg3 outputs a verify voltage in the write operation. The voltage generation units vg1 to vg3 may be, for example, a step-up circuit such as a charge pump circuit or a step-down circuit such as a regulator. Each of the step-down circuit and the step-up circuit is connected to a voltage supply line L_{P}. A power supply voltage V_{CC} or a ground voltage Vss (FIG. 1) is supplied to the voltage supply line L_{P}. The voltage supply lines L_{P} are connected to, for example, the pad electrode P. The operation voltage, which is output from the voltage generation circuit VG, is appropriately adjusted according to the control signal from the sequencer SQC.

The voltage generation circuit VG shown in FIG. 3 includes a configuration that generates a plurality of operation voltages (the program voltage, the read pass voltage, the write pass voltage, the read voltage, and the verify voltage) applied to the word line WL. The voltage generation circuit VG also includes a configuration that generates a plurality of operation voltages applied to the bit line BL, the source line SL, and the select gate lines (SGD, SGS).

### Circuit Configuration of Row Decoder RD

For example, as shown in FIG. 3, the row decoder RD (FIG. 1) includes a row control circuit RowC, a word line decoder WLD, a driver circuit DRV, and an address decoder (not shown). The row control circuit RowC includes, for example, a plurality of block decoder units blkd and a block decoder BLKD as shown in FIG. 4.

The plurality of block decoder units blkd correspond to the plurality of memory blocks BLK in the memory cell array MCA. The block decoder unit blkd includes a plurality of word line switches WLSW and a plurality of select gate line switches SGSW. The plurality of word line switches WLSW correspond to the plurality of word lines WL in the memory block BLK. The plurality of select gate line switches SGSW correspond to the drain-side select gate line SGD and the source-side select gate line SGS in the memory block BLK.

The word line switch WLSW and the select gate line switch SGSW are, for example, a field effect NMOS transistor. For example, as shown in FIG. 4, a drain electrode of the word line switch WLSW is connected to the word line WL. The drain electrode of the select gate line switch SGSW is connected to the drain-side select gate line SGD and the source-side select gate line SGS. Source electrodes of the word line switch WLSW and the select gate line switch SGSW are connected to wiring CGI. The wiring CGI is connected to all the block decoder units blkd in the row control circuit RowC. The gate electrodes of the word line switch WLSW and the select gate line switch SGSW are connected to a signal supply line BLKSEL. A plurality of signal supply lines BLKSEL correspond to all the block decoder units blkd. In addition, the signal supply line BLKSEL is connected to all of the word line switch WLSW and the select gate line switch SGSW in the block decoder unit blkd.

The block decoder BLKD (FIG. 4) decodes a block address during the read operation, the write operation, and the like. In the read operation, the write operation, and the like, for example, one signal line BLKSEL corresponding to the block address in the address register ADR (FIG. 1) enters “H” state, and the other signal lines BLKSEL enter an “L” state. For example, a predetermined drive voltage having a positive magnitude is supplied to one signal line BLKSEL, and the ground voltage Vss or the like is supplied to the other signal lines BLKSEL. Accordingly, all the word lines WL and the select gate lines SG in one memory block BLK corresponding to the block address are conductive with all the wirings CGI. In addition, all the word lines WL in the other memory blocks BLK enter a floating state.

The word line decoder WLD (FIG. 3) includes a plurality of word line decoding units wld. The plurality of word line decoding units wld correspond to the plurality of memory cells MC in the memory string MS. In the example of FIG. 3, the word line decoding unit wld includes two transistors T_{WLS} and T_{WLU}. The transistors T_{WLS} and T_{WLU} are, for example, field effect NMOS transistors. The drain electrodes of the transistors T_{WLS} and T_{WLU} are connected to the wiring CGI. The source electrode of the transistor T_{WLS} is connected to wiring CGIs. The source electrode of the transistor T_{WLU} is connected to wiring CGI_{U}. The gate electrode of the transistor T_{WLS} is connected to a signal line WLSEL_{S}. The gate electrode of the transistor T_{WLU} is connected to a signal line WLSEL_{U}. A plurality of signal lines WLSEL_{S} correspond to one transistors T_{WLS} in all the word line decoding units wld. A plurality of signal lines WLSEL_{U} correspond to the other transistors T_{WLU} in all the word line decoding units wld.

In the read operation, the write operation, and the like, for example, the signal line WLSEL_{S} corresponding to one word line decoding unit wld corresponding to page address in the address register ADR (FIG. 1) enters “H” state, and the WLSEL_{U} corresponding to this enters “L” state. In addition, the signal line WLSEL_{S} corresponding to other word line decoding unit wld enters “L” state, and the WLSEL_{U} corresponding to this enters “H” state. Further, a voltage corresponding to the selected word line WL is supplied to the wiring CGIs. A voltage corresponding to a non-selected word line WL is supplied to the wiring CGI_{U}. Thus, the voltage corresponding to the selected word line WL is supplied to one word line WL corresponding to the page address. In addition, the voltage corresponding to the non-selected word line WL is supplied to the other word lines WL.

The driver circuit DRV (FIG. 3) includes, for example, six transistors T_{DRV1} to T_{DRV6}. The transistors T_{DRV1} to T_{DRV6} are, for example, field effect NMOS transistors. The drain electrodes of the transistors T_{DRV1} to T_{DRV4} are connected to the wiring CGIs. The drain electrodes of the transistors T_{DRV5} and T_{DRV6} are connected to the wiring CGI_{U}. The source electrode of the transistor T_{DRV1} is connected to an output terminal of the voltage generation unit vg1 via a voltage supply line L_{VG1}. The source electrodes of the transistors T_{DRV2} and T_{DRV5} are connected to an output terminal of the voltage generation unit vg2 via a voltage supply line L_{VG2}. The source electrode of the transistor T_{DRV3} is connected to an output terminal of the voltage generation unit vg3 via a voltage supply line L_{VG3}. The source electrodes of transistors T_{DRV4} and T_{DRV6} are connected to the pad electrode P via the voltage supply line L_{P}. The signal lines VSEL1 to VSEL6 are connected to the gate electrodes of the transistors T_{DRV1} to T_{DRV6}, respectively.

In the read operation, the write operation, and the like, for example, one of the plurality of signal lines VSEL1 to VSEL4 corresponding to the wiring CGIs enters “H” state, and the other signal lines enter “L” state. In addition, one of the two signal lines VSEL5 and VSEL6 corresponding to the wiring CGI_{U} enters “H” state, and the other enters “L” state.

The address decoder (not shown) sequentially references row addresses RA of the address register ADR (FIG. 1) according to, for example, a control signal from the sequencer SQC (FIG. 1). The row address RA includes the block address and the page address described above. The address decoder controls the voltages of the signal lines BLKSEL, WLSEL_{S}, and WLSEL_{U} to “H” state or “L” state.

In the example of FIG. 3, the row decoder RD includes one block decoder unit blkd for each memory block BLK. The configuration may be changed as appropriate. For example, one block decoder unit blkd may be provided for two or more memory blocks BLK.

### Circuit Configuration of Sense Amplifier Module SAM

The sense amplifier module SAM (FIG. 1) detects an ON state/OFF state of the memory cell MC and acquires data indicating the state of the memory cell MC. Such an operation may be referred to as a sense operation. The sense amplifier module SAM includes, for example, a plurality of sense amplifier units. The plurality of sense amplifier units correspond to a plurality of bit lines BL. Each of the plurality of sense amplifier units includes a sense amplifier circuit and a latch circuit.

### Circuit Configuration of Cache Memory CM

The cache memory CM (FIG. 1) includes a plurality of latch circuits. The plurality of latch circuits are connected to the latch circuit in the sense amplifier module SAM via wiring DBUS. Pieces of data DAT included in the plurality of latch circuits are sequentially transferred to the sense amplifier module SAM or the input/output control circuit I/O.

A decoding circuit (not illustrated) and a switch circuit (not shown) are connected to the cache memory CM. The decoding circuit decodes a column address CA stored in the address register ADR. The switch circuit causes the latch circuit corresponding to the column address CA to be electrically connected to a bus BUS (FIG. 1) in accordance with the output signal of the decoding circuit.

### Circuit Configuration of Sequencer SQC

The sequencer SQC (FIG. 1) outputs an internal control signal to the row decoder RD, the sense amplifier module SAM, and the voltage generation circuit VG in accordance with command data D_{CMD} stored in the command register CMR. The sequencer SQC outputs status data D_{ST} indicating a state of the sequencer itself to the status register STR as appropriate.

The sequencer SQC generates a ready/busy signal and outputs the generated ready/busy signal to a terminal RY//BY. During a period (busy period) in which the terminal RY//BY is in “L” state, an access to the memory die MD is basically prohibited. During a period (ready period) in which the terminal RY//BY is in “H” state, the access to the memory die MD is permitted.

### Circuit Configuration of Input/Output Control Circuit I/O

The input/output control circuit I/O (FIG. 1) includes data signal input/output terminals DQ0 to DQ7, toggle signal input/output terminals DQS and/DQS, a plurality of input circuits, a plurality of output circuits, a shift register, and a buffer circuit. The plurality of input circuits, the plurality of output circuits, the shift register, and the buffer circuit are connected to terminals to which a power-source voltage V_{CCQ} and the ground voltage Vss are supplied, respectively.

Data input via the data signal input/output terminals DQ0 to DQ7 is output from the buffer circuit to the cache memory CM, the address register ADR, or the command register CMR in accordance with the internal control signal from the logic circuit CTR. The data, which is output via the data signal input/output terminals DQ0 to DQ7, is input to the buffer circuit from the cache memory CM or the status register STR in accordance with the internal control signal from the logic circuit CTR.

The plurality of input circuits include, for example, comparators connected to any one of the data signal input/output terminals DQ0 to DQ7 or to both of the toggle signal input/output terminals DQS and/DQS. The plurality of output circuits include, for example, off chip driver (OCD) circuits connected to any one of the data signal input/output terminals DQ0 to DQ7 or to either of the toggle signal input/output terminals DQS and/DQS.

### Circuit Configuration of Logic Circuit CTR

The logic circuit CTR (FIG. 1) receives an external control signal from a controller die CD via external control terminals/CEn, CLE, ALE, /WE, RE, and/RE, and outputs the internal control signal to the input/output control circuit I/O in response to the reception.

### Structure of Memory Die MD

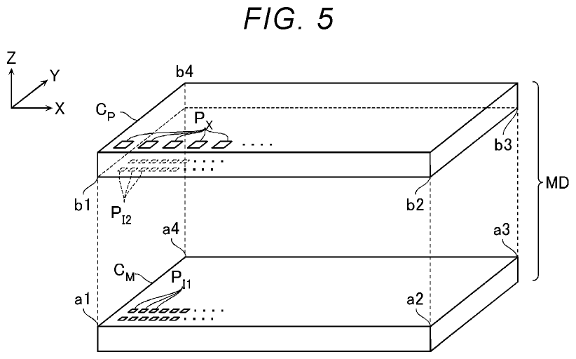

FIG. 5 is an exploded perspective view schematically showing a configuration example of the semiconductor storage device according to the first embodiment. As shown in FIG. 5, the memory die MD includes a chip C_{P} on a peripheral circuit PC side and a chip C_{M} on a memory cell array MCA side.

A plurality of external pad electrodes P_{X} to which a bonding wire (not shown) can be connected are provided on the upper surface of the chip C_{P}. A plurality of bonding electrodes P_{I2} are provided on the lower surface of the chip C_{P}. A plurality of bonding electrodes P_{I1} are provided on the upper surface of the chip C_{M}. Hereinafter, regarding the chip C_{P}, a surface on which the plurality of bonding electrodes P_{I2} are provided is referred to as a front surface, and a surface on which the plurality of external pad electrode P_{X} are provided is referred to as a rear surface. Regarding the chip C_{M}, a surface on which the plurality of bonding electrodes P_{I1} are provided is referred to as a front surface, and a surface on the opposite side of the front surface is referred to as a rear surface. In the example shown in the figure, the rear surface of the chip C_{P} is provided above the front surface of the chip C_{P}, and the front surface of the chip C_{M} is provided above the rear surface of the chip C_{M}.

The chip C_{P} and the chip C_{M} are disposed so that the front surface of the chip C_{P} faces the front surface of the chip C_{M}. The plurality of bonding electrodes P_{I2} correspond to the plurality of bonding electrodes P_{I1}, and are disposed at positions bondable to the plurality of bonding electrodes P_{I1}. The bonding electrodes P_{I1} and the bonding electrodes P_{I2} function as bonding electrodes for bonding the chip C_{M} and the chip C_{P} to each other and causing the chip C_{M} and the chip C_{P} to be electrically connected to each other. The plurality of bonding electrodes P_{I2} are connected to the plurality of bonding electrodes P_{I1}.

In the example of FIG. 5, corners b1, b2, b3, and b4 of chip C_{P} correspond to corners a1, a2, a3, and a4 of chip C_{M}, respectively.

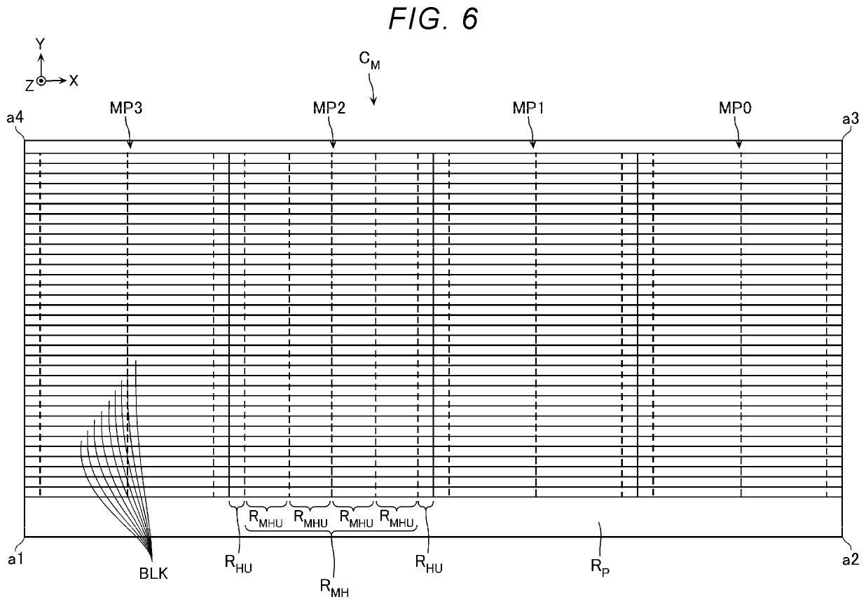

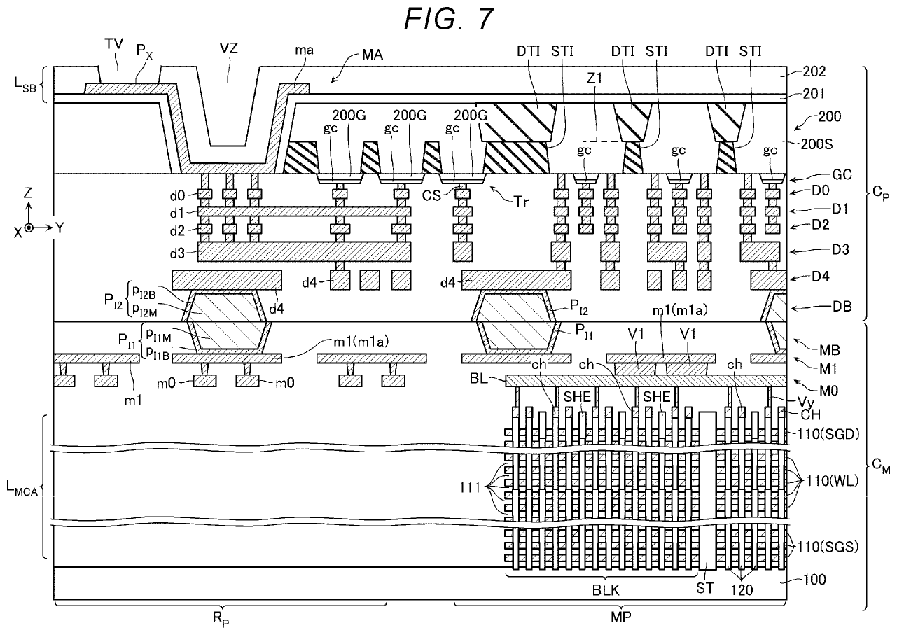

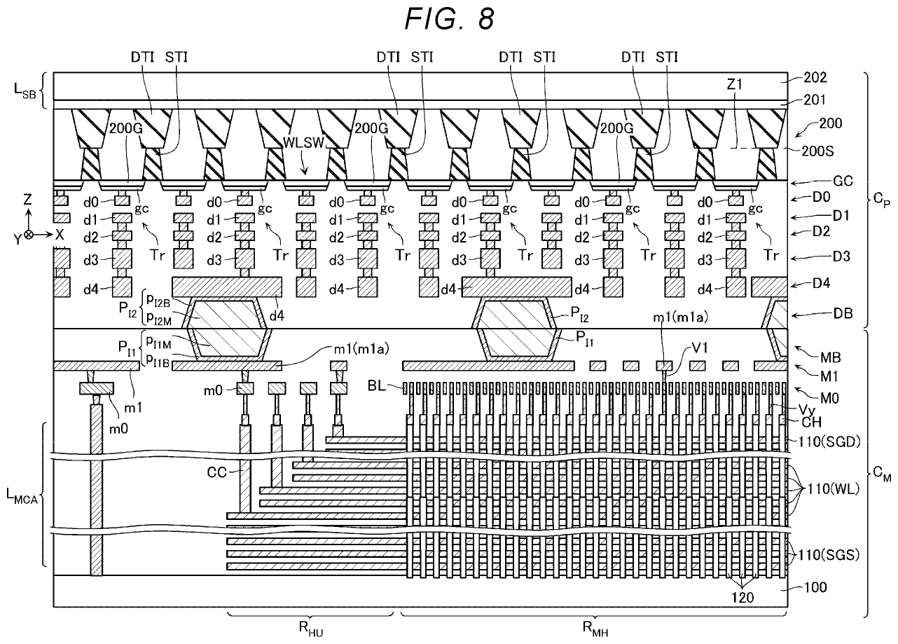

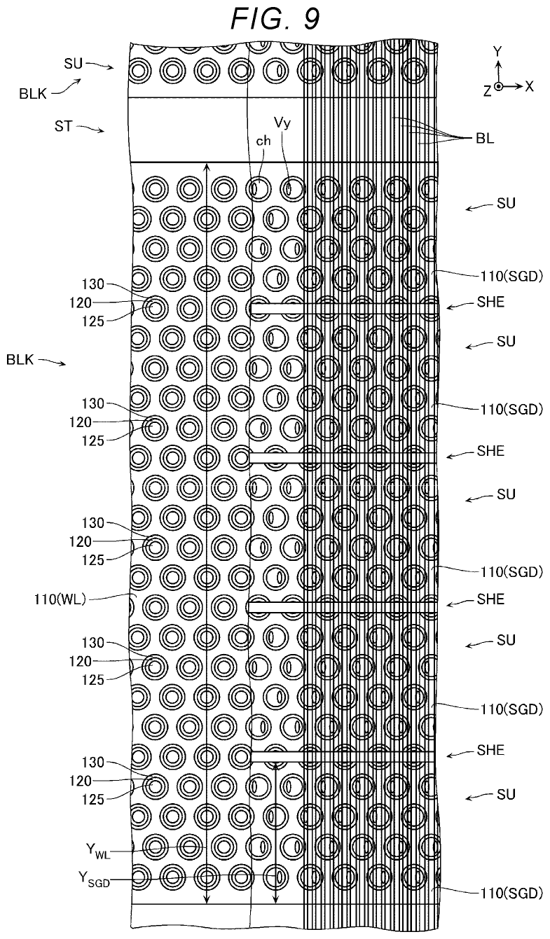

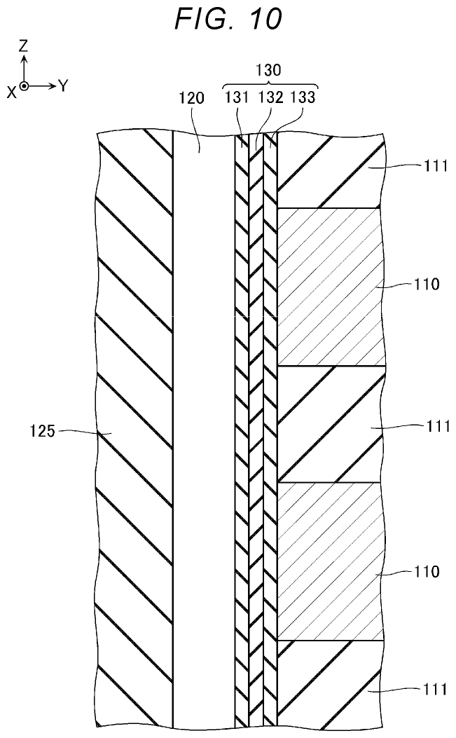

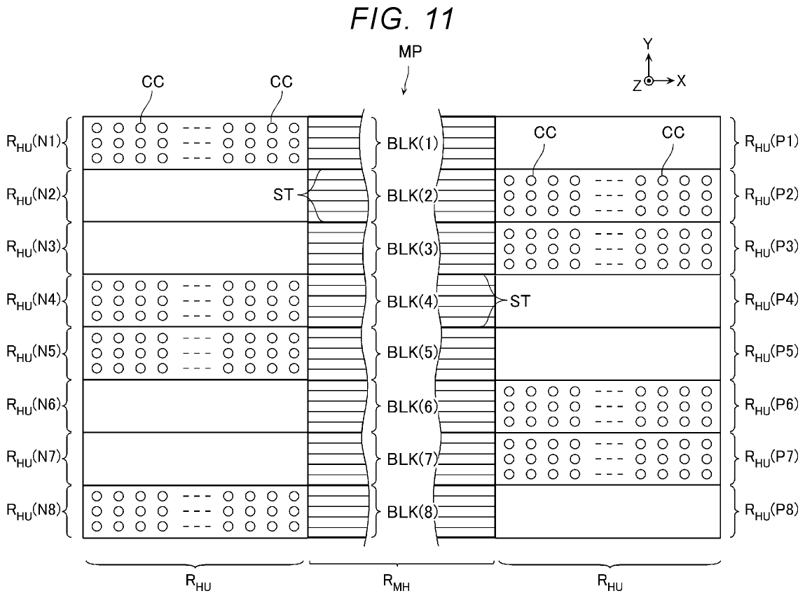

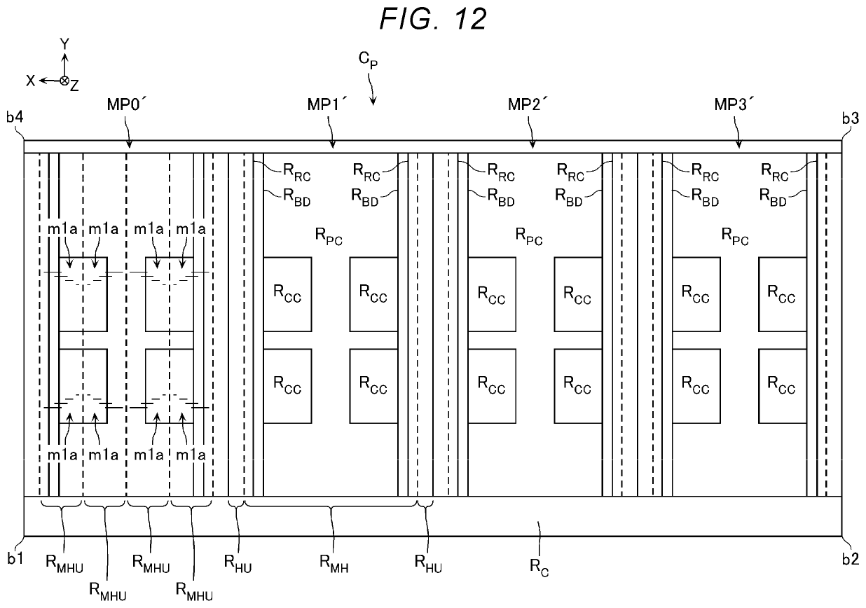

FIG. 6 is a schematic top view showing a configuration example of the chip C_{M}. In FIG. 6, a part of the configuration such as the bonding electrode P_{I1} is omitted. FIGS. 7 and 8 are schematic cross-sectional views showing a configuration of a part of the memory die MD. FIG. 9 is a schematic top view showing a configuration of a part of the chip C_{M}. In FIG. 9, an XY cross section of a position of the word line WL shown in FIG. 7 is shown in the left region, and an XY cross section of a position of the drain-side select gate line SGD shown in FIG. 7 is shown in the right region. In the right region in FIG. 9, a via contact electrodes ch and Vy and the bit lines BL are also shown in order to represent a connection portion between semiconductor columns 120 and the bit lines BL. In the left region in FIG. 9, the via contact electrodes ch and Vy and the bit lines BL are also provided but the bit lines BL are not shown. FIG. 10 is a schematic cross-sectional view showing a configuration of a part of the chip C_{M}. Although FIG. 10 shows a YZ cross section, a structure similar to that in FIG. 10 is observed even when a cross section other than the YZ cross section (for example, an XZ cross section) along a central axis of the semiconductor column 120 is observed. FIG. 11 is a schematic plan view showing a configuration example of a hook up region R_{HU}. FIG. 12 is a schematic bottom view showing a configuration example of the chip C_{P}. In FIG. 12, a part of the configuration such as the bonding electrode P_{I2} is omitted.

### Structure of Chip C_{M}

The chip C_{M} (FIG. 5) includes four memory planes MP0 to MP3 arranged in the X direction in the example of FIG. 6. The four memory planes MP0 to MP3 may be simply referred to as a memory plane MP. In addition, each of the four memory planes MP0 to MP3 includes a plurality of memory blocks BLK arranged in the Y direction. In addition, in the example of FIG. 6, each of the four memory planes MP0 to MP3 includes the hook up regions R_{HU} provided at both end portions in the X direction and a memory hole region R_{MH} provided between the hook-up regions. In addition, in the example of FIG. 6, the memory hole region R_{MH} is divided into four regions R_{MHU} in the X direction. The widths of the four regions R_{MHU} in the X direction may be the same or may be different from each other. In addition, the chip C_{M} includes a peripheral region R_{P} provided on one end side in the Y direction with respect to the four memory planes MP0 to MP3.

In the example shown in the figure, the hook up regions R_{HU} are provided at both end portions of the memory plane MP in the X direction. Such a configuration is just an example, and the specific configuration can be appropriately adjusted. For example, the hook up region R_{HU} may be provided at one end portion in the X direction instead of both end portions of the memory plane MP in the X direction. In addition, the hook up region R_{HU} may be provided at a central position or a position near the center of the memory plane MP in the X direction.

As shown in FIG. 7, the chip C_{M} includes, for example, a conductive layer 100, a memory cell array layer L_{MCA} provided above the conductive layer 100, a via contact electrode layer CH provided above the memory cell array layer L_{MCA}, a plurality of wiring layers M0 and M1 provided above the via contact electrode layer CH, and a chip bonding electrode layer MB provided above the wiring layers M0 and M1.

The conductive layer 100 may include, for example, a semiconductor layer such as silicon (Si) into which N-type impurities such as phosphorus (P) or P-type impurities such as boron (B) are implanted, may include a metal such as tungsten (W), or may include a silicide such as tungsten silicide (WSi).

The conductive layer 100 functions as a part of the source line SL (FIG. 1). Four conductive layers 100 are provided corresponding to four memory planes MP0 to MP3 (FIG. 6).

### Structure of Memory Cell Array Layer L_{MCA} in Memory Hole

Region R_{MH} of Chip C_{M}

As described with reference to FIG. 6, a plurality of memory blocks BLK arranged in the Y direction are provided in the memory cell array layer L_{MCA}. An inter-block insulating layer ST made of silicon oxide (SiO₂) or the like is provided between two memory blocks BLK adjacent to each other in the Y direction, as shown in FIG. 7. A plurality of stacked structures arranged in the Y direction and including the plurality of conductive layers 110 arranged in the Z direction correspond to the plurality of memory blocks BLK.

The memory block BLK includes, for example, a plurality of conductive layers 110 arranged in the Z direction and a plurality of semiconductor columns 120 extending in the Z direction, as shown in FIG. 7. In addition, as shown in FIG. 10, the gate insulating film 130 is provided between the plurality of conductive layers 110 and the plurality of semiconductor columns 120.

The conductive layer 110 (FIG. 7) has a substantially plate-like shape extending in the X direction. For example, the conductive layer 110 may include a stacked film of a barrier conductive film made of titanium nitride (TiN) or the like and a metal film made of tungsten (W), molybdenum (Mo), or the like. The conductive layer 110 may contain, for example, polycrystalline silicon containing impurities such as phosphorus (P) or boron (B). An inter-layer insulating layer 111 made of silicon oxide (SiO₂) or the like is provided between the plurality of conductive layers 110 arranged in the Z direction.

Among the plurality of conductive layers 110 (FIG. 7), one or a plurality of conductive layers 110 located in the lowermost layer function as the gate electrode of the source-side select transistor STS (FIG. 2) and the source-side select gate line SGS. These conductive layers 110, referred to herein as SGS conductive layers, are electrically independent for each memory block BLK.

In addition, the plurality of conductive layers 110 located above the SGS conductive layers function as the gate electrodes and the word lines WL of the memory cells MC (FIG. 2). These conductive layers 110, referred to herein as WL conductive layers, are electrically independent for each memory block BLK.

In addition, one or a plurality of conductive layers 110 located above the WL conductive layers function as the gate electrode of the drain-side select transistor STD and the drain-side select gate line SGD. These conductive layers 110, referred to herein as SGD conductive layers, are electrically independent for each string unit SU. For example, as shown in FIG. 9, a width Y_{SGD} of the SGD conductive layers in the Y direction is smaller than a width Y_{WL} of the WL conductive layer in the Y direction. In addition, an inter-string unit insulating layer SHE made of silicon oxide (SiO₂) or the like is provided between the two SGD conductive layers adjacent to each other in the Y direction.

For example, as shown in FIG. 9, the semiconductor columns 120 are arranged in the X direction and the Y direction in a predetermined pattern. The semiconductor columns 120 function as channel regions of the plurality of memory cells MC and select transistors (STD, STS) in one memory string MS (FIG. 2), respectively. The semiconductor column 120 contains, for example, polycrystalline silicon (Si). For example, the semiconductor column 120 has a substantially cylindrical shape, and an insulating layer 125 made of silicon oxide or the like is provided at the central portion of the semiconductor column 120. The outer peripheral surface of the semiconductor column 120 is surrounded by the plurality of conductive layers 110, and faces the plurality of conductive layers 110.

In addition, an impurity region (not shown) is provided at a lower end of the semiconductor column 120 (FIG. 7). The impurity region is connected to the conductive layer 100. The impurity region contains, for example, N-type impurities such as phosphorus (P) or P-type impurities such as boron (B).

In addition, an impurity region (not shown) is provided at an upper end of the semiconductor column 120 (FIG. 7). The impurity region is connected to the bit line BL via the via contact electrode ch and the via contact electrode Vy. The impurity region contains, for example, N-type impurities such as phosphorus (P).

The gate insulating film 130 has a substantially cylindrical shape covering the outer peripheral surface of the semiconductor column 120, for example, as shown in FIG. 9. For example, as shown in FIG. 10, the gate insulating film 130 includes a tunnel insulating film 131, a charge storage film 132, and a block insulating film 133, which are stacked between the semiconductor column 120 and the conductive layer 110. The tunnel insulating film 131 and the block insulating film 133 contain, for example, silicon oxide (SiO₂), silicon oxynitride (SiON), or the like. The charge storage film 132 includes, for example, a film that is made of silicon nitride (SiN) or the like and is capable of storing charges. The tunnel insulating film 131, the charge storage film 132, and the block insulating film 133 have a substantially cylindrical shape, and extend in the Z direction along the outer peripheral surface of the semiconductor column 120 except for a contact portion between the semiconductor column 120 and the conductive layer 100.

FIG. 10 shows an example in which the gate insulating film 130 includes the charge storage film 132 made of silicon nitride or the like. The gate insulating film 130 may include, for example, a floating gate made of polycrystalline silicon containing N-type or P-type impurities.

Structure of Memory Cell Array Layer L_{MCA} in Hook Up Region R_{HU} of Chip C_{M}

As shown in FIG. 8, a plurality of via contact electrodes CC (contacts) are provided in the hook up region R_{HU}. The plurality of via contact electrodes CC each extend in the Z direction and are connected to the conductive layer 110 (WL, SGD, and SGS) at the lower end.

As shown in FIG. 11, the hook up regions R_{HU} are provided on the negative side in the X direction and the positive side in the X direction of the memory plane MP, and a memory hole region R_{MH} is provided between two hook up regions R_{HU}. In the memory hole region R_{MH}, first to eighth memory blocks counted from the positive side in the Y direction are assumed to be the memory blocks BLK (1) to BLK (8). The hook up region R_{HU} on the negative side in the X direction is divided into hook up regions R_{HU} (N1) to R_{HU} (N8) corresponding to the memory blocks BLK (1) to BLK (8). In addition, the hook up region R_{HU} on the positive side in the X direction is divided into hook up regions R_{HU} (P1) to R_{HU} (P8) corresponding to the memory blocks BLK (1) to BLK (8).

In the hook up regions R_{HU} (N1), R_{HU} (N4), R_{HU} (N5), R_{HU} (N8), R_{HU} (P2), R_{HU} (P3), R_{HU} (P6), and R_{HU} (P7), a plurality of columns of three via contact electrodes CC arranged in the Y direction are arranged in the X direction.

The plurality of via contact electrodes CC of the hook up region R_{HU} (N1) are connected to the conductive layer 110 of each layer in the memory block BLK (1). The plurality of via contact electrodes CC of the hook up region R_{HU} (P2) are connected to the conductive layer 110 of each layer in the memory block BLK (2). The plurality of via contact electrodes CC of the hook up region R_{HU} (P3) are connected to the conductive layer 110 of each layer in the memory block BLK (3). The plurality of via contact electrodes CC of the hook up region R_{HU} (N4) are connected to the conductive layer 110 of each layer in the memory block BLK (4). The plurality of via contact electrodes CC of the hook up region R_{HU} (N5) are connected to the conductive layer 110 of each layer in the memory block BLK (5). The plurality of via contact electrodes CC of the hook up region R_{HU} (P6) are connected to the conductive layer 110 of each layer in the memory block BLK (6). The plurality of via contact electrodes CC of the hook up region R_{HU} (P7) are connected to the conductive layer 110 of each layer in the memory block BLK (7). The plurality of via contact electrodes CC of the hook up region R_{HU} (N8) are connected to the conductive layer 110 of each layer in the memory block BLK (8).

### Structure of Via Contact Electrode Layer CH

The plurality of via contact electrodes ch provided in the via contact electrode layer CH (FIG. 7) are electrically connected to at least one of the component in the memory cell array layer L_{MCA} and the component in the chip C_{P}, for example.

The via contact electrode layer CH includes the plurality of via contact electrodes ch. The plurality of via contact electrodes ch may include, for example, a stacked film of a barrier conductive film made of titanium nitride (TiN) or the like and a metal film made of tungsten (W) or the like. The via contact electrodes ch correspond to the plurality of semiconductor columns 120 and are connected to the plurality of semiconductor columns 120.

### Structure of Wiring Layers M0 and M1 of Chip C_{M}

The plurality of wirings provided in the wiring layers M0 and M1 (FIG. 7) are electrically connected to at least one of the component in the memory cell array layer L_{MCA} and the component in the chip C_{P}, for example.

For example, as shown in FIG. 7, the wiring layer M0 includes a plurality of wirings m0. The plurality of wirings m0 may include, for example, a stacked film of a barrier conductive film made of titanium nitride (TiN), tantalum nitride (TaN), or a stacked film made of tantalum nitride (TaN) and tantalum (Ta), and a metal film made of copper (Cu). Some of the plurality of wirings m0 function as the bit lines BL. The bit lines BL are arranged in the X direction and extend in the Y direction, for example, as shown in FIG. 9.

For example, as shown in FIG. 7, the wiring layer M1 includes a plurality of wirings ml. The plurality of wirings ml may include, for example, a stacked film of a barrier conductive film made of titanium nitride (TiN) or the like and a metal film made of tungsten (W) or the like.

### Structure of Chip Bonding Electrode Layer MB

The plurality of components provided in the chip bonding electrode layer MB (see FIGS. 7 and 8) are electrically connected to at least one of the component in the memory cell array layer L_{MCA} and the component in the chip C_{P}.

The chip bonding electrode layer MB includes a plurality of bonding electrodes P_{I1} (which are bonding pads). The plurality of bonding electrodes P_{I1} may include, for example, a stacked film of a barrier conductive film p_{I1B} made of titanium nitride (TiN), tantalum nitride (TaN), or a stacked film made of tantalum nitride (TaN) and tantalum (Ta), and a metal film prim made of copper (Cu).

### Structure of Chip C_{P}

The chip C_{P} includes regions MP0′ to MP3′ overlapping with the four memory planes MP0 to MP3 arranged in the X direction, as shown in the example of FIG. 12. In both end portions of the four regions MP0′ to MP3′ in the X direction, a row control circuit region R_{RC} is provided. Further, between two row control circuit regions R_{RC}, two block decoder regions R_{BD} arranged in the X direction are provided. In addition, a peripheral circuit region R_{PC} is provided between the two block decoder regions R_{BD}. The peripheral circuit region R_{PC} is provided with four column control circuit regions R_{CC} arranged in the X direction and the Y direction. In addition, although not shown, a circuit is also disposed in other regions in the peripheral circuit region R_{PC}. In addition, a circuit region R_{C} is provided in a region of the chip C_{P} facing the peripheral region R_{P} of the chip C_{M} (FIG. 6).

The plurality of block decoder units blkd described with reference to FIGS. 3 and 4 are provided in the row control circuit region R_{RC}. That is, the plurality of word line switches WLSW and the plurality of select gate line switches SGSW that make up the plurality of block decoder units blkd are provided in the row control circuit region R_{RC}. The block decoder BLKD described with reference to FIG. 4 is provided in the block decoder region R_{BD}. The column control circuit region R_{CC} is provided with the sense amplifier module SAM described with reference to FIG. 1. An input/output circuit (not shown) is provided in the circuit region R_{C}. The input/output circuit is connected to the external pad electrode P_{X} via wiring layers D0, D1, and the like described later.

In addition, in FIG. 12, a region overlapping the hook up region R_{HU} (FIG. 6) when viewed in the Z direction is indicated by a dotted line. In the example of FIG. 12, a part of the row control circuit region R_{RC} is provided in the region overlapping the hook up region R_{HU} (FIG. 6) when viewed in the Z direction. In addition, a part of the row control circuit region R_{RC} is provided in a region overlapping the memory hole region R_{MH} (FIG. 6) when viewed in the Z direction. In addition, in the example of FIG. 12, the width of the row control circuit region R_{RC} in the X direction is larger than the width of the hook up region R_{HU} (FIG. 6) in the X direction. As described above, the plurality of word line switches WLSW and the select gate line switches in the row control circuit region R_{RC} are provided at positions overlapping a part of the hook up region R_{HU} and the memory hole region R_{MH} when viewed in the Z direction.

In addition, in the example of FIG. 12, the central position of the column control circuit region R_{CC} in the X direction coincides with the boundary between the first and second regions R_{MHU} counted from the positive side in the X direction or the boundary between the third and fourth regions R_{MHU} counted from the positive side in the X direction. However, in alternative embodiments, the central position of the column control circuit region R_{CC} in the X direction may not coincide with the boundary between the first and second regions R_{MHU} counted from the positive side in the X direction or the boundary between the third and fourth regions R_{MHU} counted from the positive side in the X direction.

In addition, as shown in FIG. 7, the chip C_{P} includes, for example, a base layer L_{SB}, a semiconductor substrate 200 provided below the base layer L_{SB}, an electrode layer GC provided below the semiconductor substrate 200, wiring layers D0, D1, D2, D3, and D4 provided below the electrode layer GC, and a chip bonding electrode layer DB provided below the wiring layers D0, D1, D2, D3, and D4.

Structure of Base Layer L_{SB} of Chip C_{P}

The base layer L_{SB} includes, for example, an insulating layer 201 provided on an upper surface of the semiconductor substrate 200, a rear surface wiring layer MA provided on a bottom surface of an opening of a region VZ, an inner peripheral surface, and a peripheral portion of the opening, and an insulating layer 202 provided on an upper surface of the rear surface wiring layer MA and an upper surface of the insulating layer 201, as shown in FIG. 7. The insulating layer 201 contains, for example, silicon oxide (SiO₂) and the like.

The rear surface wiring layer MA includes a plurality of wirings ma. The plurality of wirings ma may include, for example, aluminum (Al) or the like. In addition, at least some of the plurality of wirings ma function as the external pad electrode P_{X}. The wiring ma is provided in the peripheral region R_{P}. The wiring ma is electrically connected to the component in the wiring layers D0 to D4 on the bottom surface of the opening VZ. In addition, a part of the wiring ma is exposed to the outside of the memory die MD via an opening TV provided in the insulating layer 202. The insulating layer 202 is a passivation layer made of an insulating material such as polyimide.

### Structure of Semiconductor Substrate 200 of Chip C_{P}

The semiconductor substrate 200 contains P-type silicon (Si) containing P-type impurities such as boron (B), for example. In addition, the semiconductor substrate 200 includes, for example, a semiconductor substrate region 200S, an insulating member STI, and an insulating member DTI. The semiconductor substrate region 200S includes some of the plurality of transistors Tr that make up the peripheral circuit PC and a plurality of capacitors or the like. Some of the plurality of transistors Tr function as the word line switch WLSW and the select gate line switch SGSW.

The insulating member STI includes, for example, silicon oxide (SiO₂). The insulating member STI is provided between two transistors Tr adjacent to each other in the X direction or in the Y direction. The insulating member STI extends in the Z direction from the front surface (lower surface as depicted in FIG. 7) of the semiconductor substrate 200 to a position Z1 between the front surface and the rear surface of the semiconductor substrate 200.

The insulating member STI includes a portion extending in the X direction or in the Y direction as described below. A side surface in the Y direction of the portion of the insulating member STI extending in the X direction has a tapered shape in the XZ cross section. That is, the width in the Y direction at the lower end of this portion (i.e., the width in the Y direction at the height position of the lower surface of the semiconductor substrate 200) is larger than the width in the Y direction at the upper end of this portion (i.e., the width in the Y direction at the position Z1). Similarly, the side surface in the X direction of the portion of the insulating member STI extending in the Y direction has a tapered shape in the YZ cross section. That is, the width in the X direction at the lower end of this portion (i.e., the width in the X direction at the height position of the lower surface of the semiconductor substrate 200) is larger than the width in the X direction at the upper end of this portion (i.e., the width in the X direction at the position Z1).

The insulating member DTI includes, for example, silicon oxide (SiO₂). The insulating member DTI is provided at a position overlapping the insulating member STI when viewed in the Z direction between two transistors Tr adjacent to each other in the X direction or in the Y direction. The insulating member DTI is basically provided at a position overlapping the insulating member STI when viewed in the Z direction. However, a part of the insulating member DTI is provided at a position that does not overlap the insulating member STI when viewed in the Z direction.

The insulating member DTI extends in the Z direction from the rear surface (upper surface as depicted in FIG. 7) of the semiconductor substrate 200 to the position Z1. The insulating member DTI includes a portion extending in the X direction or in the Y direction as described below. The side surface in the Y direction of a portion of the insulating member DTI extending in the X direction has a tapered shape in the XZ cross section. That is, the width in the Y direction at the lower end of this portion (i.e. the width in the Y direction at the height position of the lower surface of the semiconductor substrate 200) is larger than the width in the Y direction at the upper end of this portion (i.e., the width in the Y direction at the position Z1). Similarly, the side surface in the X direction of a portion of the insulating member DTI extending in the Y direction has a tapered shape in the YZ cross section. That is, the width in the X direction at the lower end of this portion (i.e., the width in the X direction at the height position of the lower surface of the semiconductor substrate 200) is larger than the width in the X direction at the upper end of this portion (i.e., the width in the X direction at the position Z1).

The width in the Y direction at the upper end of the portion of the insulating member DTI extending in the X direction (i.e., the width in the Y direction at the height position of the upper surface of the semiconductor substrate 200) is larger than the width in the Y direction at the lower end of the portion of the insulating member STI extending in the X direction (i.e., the width in the Y direction at the height position of the lower surface of the semiconductor substrate 200). In addition, the width in the Y direction at the lower end of the portion of the insulating member DTI extending in the X direction (i.e., the width in the Y direction at the position Z1) is larger than the width in the Y direction at the upper end of the portion of the insulating member STI extending in the X direction (i.e., the width in the Y direction at the position Z1).

Similarly, the width in the X direction at the upper end of the portion of the insulating member DTI extending in the Y direction (i.e., the width in the X direction at the height position of the upper surface of the semiconductor substrate 200) is larger than the width in the X direction at the lower end of the portion of the insulating member STI extending in the Y direction (i.e., the width in the X direction at the height position of the lower surface of the semiconductor substrate 200). In addition, the width in the X direction at the lower end of the portion of the insulating member DTI extending in the Y direction (i.e., the width in the X direction at the position Z1), is larger than the width in the X direction at the upper end of the portion of the insulating member STI extending in the Y direction (i.e., the width in the X direction at the position Z1).

### Structure of Electrode Layer GC of Chip C_{P}

As shown in FIG. 7, for example, the electrode layer GC is provided on the lower surface of the semiconductor substrate 200 via an insulating layer 200G. The electrode layer GC includes a plurality of electrodes gc that face the front surface of the semiconductor substrate 200. In addition, the plurality of electrodes gc provided in each region and the electrode layer GC of the semiconductor substrate 200 are connected to the via contact electrode (contact) CS.

The semiconductor substrate region 200S functions as a channel region of the plurality of transistors Tr that make up the peripheral circuit PC and one electrode of the plurality of capacitors.

The plurality of electrodes gc provided in the electrode layer GC function as gate electrodes of the plurality of transistors Tr that make up the peripheral circuit PC, and the other electrode of the plurality of capacitors, respectively.

As shown in FIG. 7, the via contact electrode CS extends in the Z direction and is connected to the upper surface of the semiconductor substrate 200 or the electrode gc at the upper end. An impurity region containing N-type impurities or P-type impurities is provided at a portion at which the via contact electrode CS and the semiconductor substrate 200 are connected to each other. The via contact electrode CS may include, for example, a stacked film of a barrier conductive film made of titanium nitride (TiN) or the like and a metal film made of tungsten (W) or the like.

### Structure of Wiring Layers D0, D1, D2, D3, and D4 of Chip C_{P}

For example, as shown in FIG. 8, the plurality of wirings provided in the wiring layers D0, D1, D2, D3, and D4 are electrically connected to at least one of the component in the memory cell array layer L_{MCA} and the component in the chip C_{P}.

The wiring layers D0, D1, and D2 include a plurality of wirings d0, d1, and d2, respectively. The plurality of wirings d0, d1, and d2 may include, for example, a stacked film of a barrier conductive film made of titanium nitride (TiN) or the like and a metal film made of tungsten (W) or the like.

The wiring layers D3 and D4 include a plurality of wirings d3 and d4, respectively. The plurality of wirings d3 and d4 may include, for example, a stacked film of a barrier conductive film made of titanium nitride (TiN), tantalum nitride (TaN), or a stacked film made of tantalum nitride (TaN) and tantalum (Ta), and a metal film made of copper (Cu).

### Structure of Chip Bonding Electrode Layer DB

The plurality of wirings provided in the chip bonding electrode layer DB are electrically connected to at least one of the component in the memory cell array layer L_{MCA} and the component in the chip C_{P}, for example.

The chip bonding electrode layer DB includes a plurality of bonding electrodes P_{I2}. The plurality of bonding electrodes P_{I2} may include, for example, a stacked film of a barrier conductive film p_{I2B} made of titanium nitride (TiN), tantalum nitride (TaN), or a stacked film made of tantalum nitride (TaN) and tantalum (Ta), and a metal film p_{I2M} made of copper (Cu).

When the metal films p_{I1M} and p_{I2M} of copper (Cu) or the like are used for the bonding electrode P_{I1} and the bonding electrode P_{I2}, the metal film prim and the metal film p_{I2M} are integrated with each other, and it is difficult to check the boundary therebetween. The bonding structure can be checked by the distortion of the bonding shape of the bonding electrode P_{I1} and the bonding electrode P_{I2} due to the misalignment, and the misalignment of the barrier conductive films p_{I1B} and p_{I2B}. In addition, when the bonding electrode P_{I1} and the bonding electrode P_{I2} are formed by the damascene method, each of the side surfaces has a tapered shape. Therefore, a side wall shape of the cross section in the Z direction of a portion where the bonding electrode P_{I1} and the bonding electrode P_{I2} are bonded is not a linear shape, and is a non-rectangular shape. In addition, when the bonding electrode P_{I1} and the bonding electrode P_{I2} are bonded, the bottom surface, the side surface, and the upper surface of each Cu forming them are covered with the barrier metal. In contrast, in a wiring layer using general Cu, an insulating layer (SiN, SiCN, or the like) having an oxidation preventing function of Cu is provided on the upper surface of Cu, and the barrier metal is not provided. Therefore, a distinction from a general wiring layer can be made even when the misalignment in bonding does not occur.

### Arrangement Pattern of Word Line Switch WLSW, Select Gate Line Switch SGSW, and Insulating Member STI in Row Control Circuit Region R_{RC}

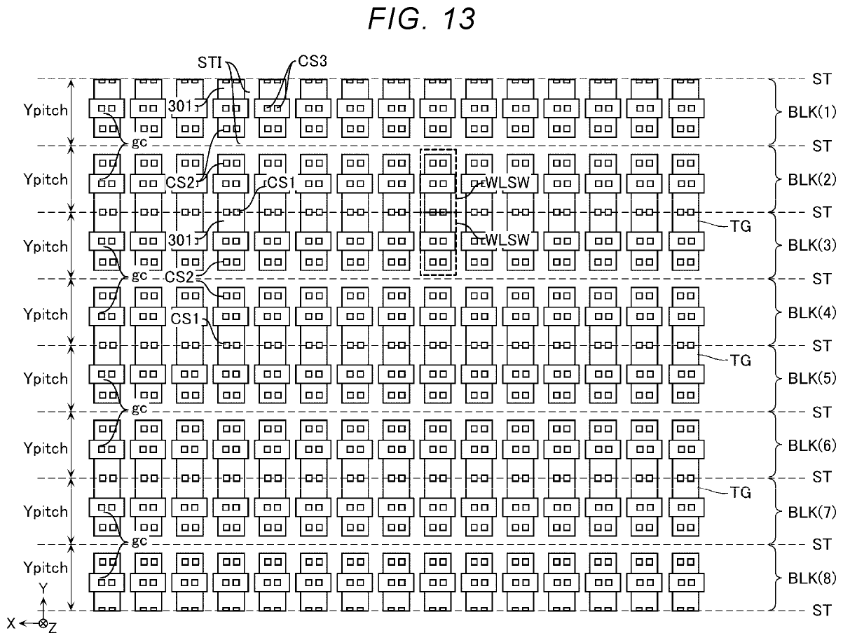

Next, the arrangement pattern of the word line switch WLSW, the select gate line switch SGSW, and the insulating member STI in the row control circuit region R_{RC} will be described with reference to FIGS. 13 and 14. FIGS. 13 and 14 are schematic bottom views showing examples of the arrangement pattern of the word line switch WLSW, the select gate line switch SGSW, and the insulating member STI in the semiconductor substrate 200 in the row control circuit region R_{RC}. In addition, in FIGS. 13 and 14, dotted lines indicating the boundary of the memory blocks BLK are shown in order to describe the correspondence relationship between the word line switch WLSW and the memory block BLK.

FIG. 13 shows two word line switches WLSW (transistors) having a common source region. Hereinafter, such two word line switches WLSW (transistors) are referred to as a “transistor group TG”.

As shown in FIG. 13, the transistor group TG includes a semiconductor region (diffusion region) 301 that extends in the Y direction. The semiconductor region 301 is a part of the lower surface of the semiconductor substrate region 200S described with reference to FIG. 7 and the like. The semiconductor regions 301 are arranged in the Y direction and are arranged in the X direction. The insulating member STI is formed around the semiconductor region 301. That is, the portion of the insulating member STI extending in the Y direction described above is provided between two semiconductor regions 301 adjacent to each other in the X direction. In addition, the portion of the insulating member STI extending in the X direction described above is provided between two semiconductor regions 301 adjacent to each other in the Y direction. In addition, via contact electrodes CS2 functioning as drain terminals of the word line switch WLSW are provided at both end portions of the semiconductor region 301 in the Y direction. In addition, via contact electrodes CS1 functioning as common source terminals of two word line switches WLSW are provided between the via contact electrodes CS2. In addition, the electrode gc is provided between the via contact electrode CS2 that functions as the drain terminal and the via contact electrode CS1 that functions as the source terminal. The electrode gc is provided with a via contact electrode CS3.

As shown in FIG. 13, among the pair of semiconductor regions 301 arranged in the Y direction, the position of the center line, which is equidistant from the end portion on the negative side in the Y direction of the semiconductor region 301 provided on the positive side in the Y direction and the end portion on the positive side in the Y direction of the semiconductor region 301 provided on the negative side in the Y direction, coincides with the position of the inter-block insulating layer ST (FIGS. 7 and 9) when viewed in the Z direction. In addition, the position of the center line of the semiconductor region 301 in the Y direction also coincides with the position of the inter-block insulating layer ST (FIGS. 7 and 9) when viewed in the Z direction. The interval between the inter-block insulating layers ST arranged in the Y direction is the same as the pitch of the word line switch WLSW in the Y direction (Ypitch in FIG. 13). That is, in the present embodiment, the pitch of the word line switch WLSW in the Y direction is the same as the pitch of the memory block BLK in the Y direction. The fact that the pitches of the word line switch WLSW and the memory block BLK in the Y direction are the same may be expressed as 1Tr/1BLK.

FIG. 13 shows the structure of the word line switch WLSW, and the structure of the select gate line switch SGSW may also be the same as the structure of the word line switch WLSW.

In FIG. 14, among the plurality of word line switches WLSW, a word line switch provided at a position overlapping the memory block BLK (1) when viewed in the Z direction and provided in the row control circuit region R_{RC} on the negative side in the X direction is denoted as a word line switch WLSW (1L). Similarly, among the plurality of word line switches WLSW, word line switches provided at positions overlapping the memory block BLK (2) to the memory block BLK (6) when viewed in the Z direction and provided in the row control circuit region R_{RC} on the negative side in the X direction are denoted as word line switches WLSW (2L) to WLSW (6L).

Further, in FIG. 14, among the plurality of word line switches WLSW, a word line switch provided at a position overlapping the memory block BLK (1) when viewed in the Z direction and provided in the row control circuit region R_{RC} on the positive side in the X direction is denoted as a word line switch WLSW (1R). Similarly, among the plurality of word line switches WLSW, word line switches provided at positions overlapping the memory block BLK (2) to the memory block BLK (6) when viewed in the Z direction and provided in the row control circuit region R_{RC} on the positive side in the X direction are denoted as word line switches WLSW (2R) to WLSW (6R).

As described with reference to FIG. 11, the plurality of via contact electrodes CC connected to the plurality of conductive layers 110 in the memory block BLK (1) are provided on the negative side in the X direction with respect to the memory hole region R_{MH}. Here, the plurality of via contact electrodes CC are electrically connected to the via contact electrodes CS2 of the plurality of word line switches WLSW (1L) arranged in the X direction and the plurality of word line switches WLSW (2L) arranged in the X direction via the bonding electrodes P_{I1}, P_{I2}, and the wiring layers D0 to D4.

Similarly, the plurality of via contact electrodes CC (see FIG. 11) connected to the plurality of conductive layers 110 in the memory block BLK (2) are electrically connected to the via contact electrodes CS2 of the plurality of word line switches WLSW (1R) arranged in the X direction and the plurality of word line switches WLSW (2R) arranged in the X direction via the bonding electrodes P_{I1}, P_{I2}, and the wiring layers D0 to D4.

Similarly, the plurality of via contact electrodes CC (see FIG. 11) connected to the plurality of conductive layers 110 in the memory block BLK (3) are electrically connected to the via contact electrodes CS2 of the plurality of word line switches WLSW (3R) arranged in the X direction and the plurality of word line switches WLSW (4R) arranged in the X direction via the bonding electrodes P_{I1}, P_{I2}, and the wiring layers D0 to D4.

Similarly, the plurality of via contact electrodes CC (see FIG. 11) connected to the plurality of conductive layers 110 in the memory block BLK (4) are electrically connected to the via contact electrodes CS2 of the plurality of word line switches WLSW (3L) arranged in the X direction and the plurality of word line switches WLSW (4L) arranged in the X direction via the bonding electrodes P_{I1}, P_{I2}, and the wiring layers D0 to D4.

As described above, the pair of word line switches WLSW provided in the width of the pair of memory blocks BLK are connected to the conductive layer 110 (word line WL) of the same memory block BLK. The connection between the select gate line SG and the select gate line switch SGSW is also the same.

### Arrangement Pattern of Insulating Member DTI in Row Control Circuit Region R_{RC}

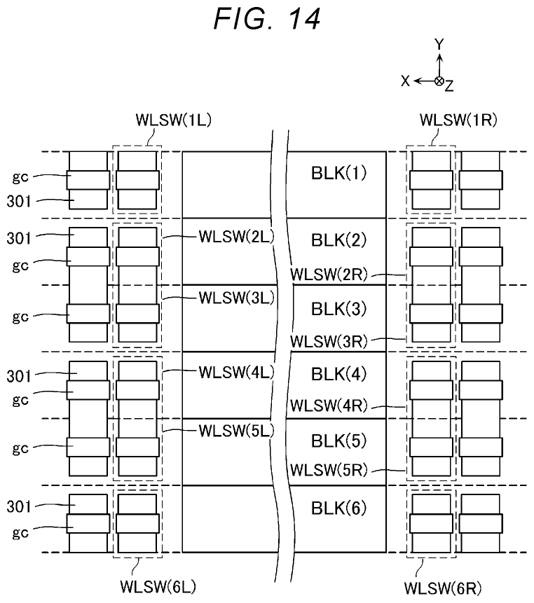

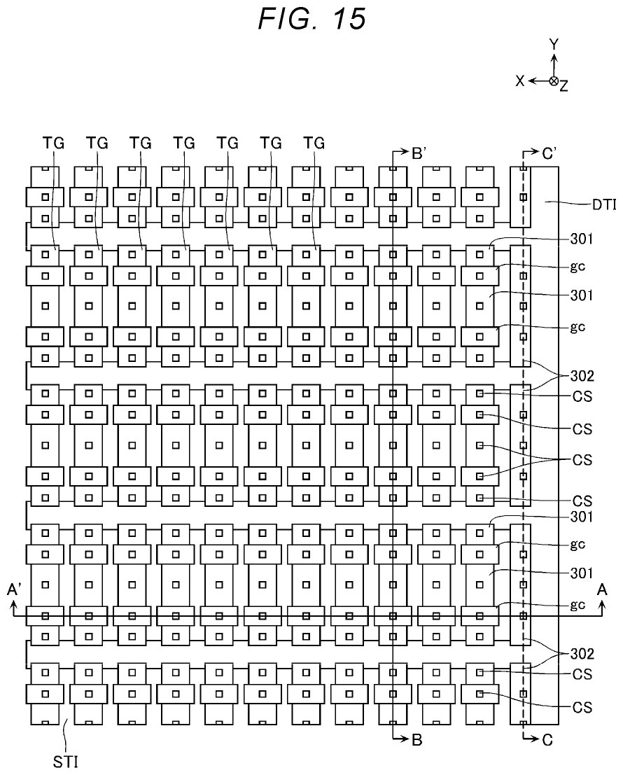

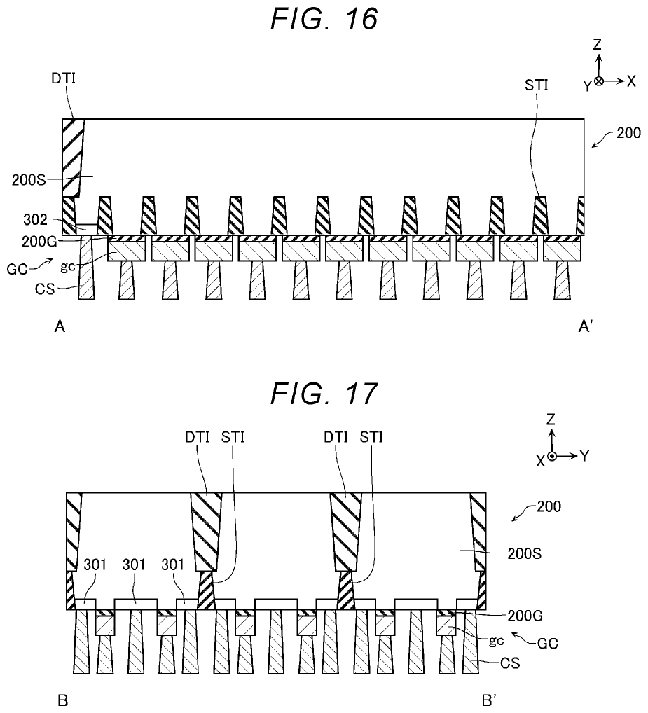

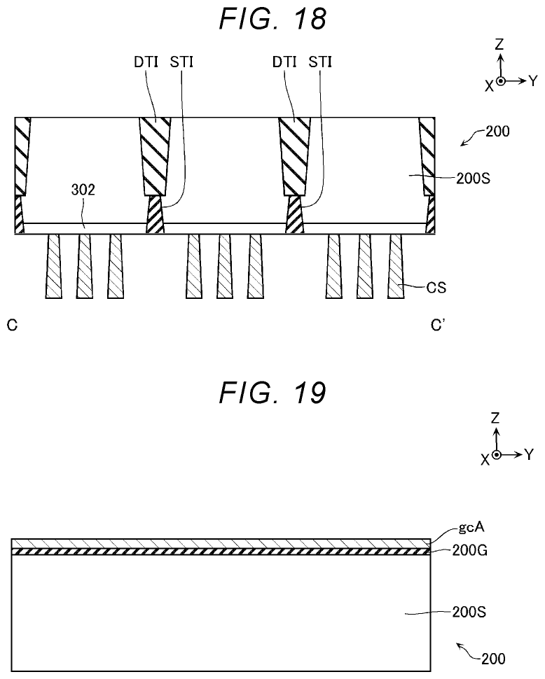

Next, the arrangement pattern of the insulating member DTI in the row control circuit region R_{RC} will be described with reference to FIGS. 15 to 18. FIG. 15 is a schematic bottom view showing an example of the arrangement pattern of the insulating member DTI in the semiconductor substrate 200 in the row control circuit region R_{RC}. FIGS. 16, 17, and 18 are schematic cross-sectional views showing examples of the arrangement pattern of the insulating member DTI in the semiconductor substrate 200 in the row control circuit region R_{RC}. While FIGS. 15 to 18 illustrate a configuration of a part of the chip C_{P}, the scope of the embodiments should not be limited to the specific number, shape, configuration, and the like which are illustrated in FIGS. 15 to 18. FIG. 16 is a view when the configuration shown in FIG. 15 is cut along the line A-A′ and viewed in a direction of an arrow. FIG. 17 is a view when the configuration shown in FIG. 15 is cut along the line B-B′ and viewed in a direction of an arrow. FIG. 18 is a view when the configuration shown in FIG. 15 is cut along the line C-C′ and viewed in a direction of an arrow.

FIG. 15 basically shows the same configuration as the configuration described with reference to FIG. 13. In FIG. 15, the insulating member DTI is shown. In the example shown in the figure, the plurality of transistor groups TG arranged in the X direction are surrounded by two portions of the insulating member DTI extending in the X direction (only one of which is shown) and two portions of the insulating member DTI extending in the Y direction. That is, the portion of the insulating member DTI extending in the X direction is formed on both end sides of the transistor group TG in the Y direction, and extends in the X direction along the plurality of transistor groups TG arranged in the X direction. In addition, the portion of the insulating member DTI extending in the Y direction is formed on both end sides in the X direction of the transistor group TG arranged in the X direction when viewed in the Z direction, and is connected to the portion of the insulating member DTI extending in the X direction. The portion of the insulating member DTI extending in the X direction extends in the X direction between two transistor groups TG adjacent to each other in the Y direction.

In addition, FIG. 15 shows a body contact region 302. The body contact region 302 is provided on a part of the lower surface of the semiconductor substrate region 200S described with reference to FIG. 7 and the like. As shown in FIGS. 16 and 18, the via contact electrode CS (contact) functioning as a front surface contact of the chip C_{P} is provided on the lower surface of the body contact region 302. The body contact region 302 is a contact impurity region and includes P-type impurities such as boron (B), that is, the same conductivity-type impurities as the semiconductor substrate region 200S. The impurity concentration of the body contact region 302 is higher than the impurity concentration of the semiconductor substrate region 200S.

As shown in FIGS. 15, 16, and 18, the body contact region 302 is separated from the transistor group TG arranged in the X direction on one end side of the transistor group TG arranged in the X direction. The body contact region 302 is electrically connected to the channel region of the word line switch WLSW corresponding to the plurality of transistor groups TG arranged in the X direction surrounded by the insulating member DTI.

Here, in the row control circuit region R_{RC}, as described above, the insulating member DTI is provided at a position overlapping a part of the insulating member STI when viewed in the Z direction. As a result, the semiconductor substrate region 200S is divided into a plurality of regions by the insulating member DTI and the insulating member STI. That is, as shown in FIGS. 15 to 17, the insulating member DTI electrically separates the substrate regions of the plurality of word line switches WLSW arranged in the X direction adjacent to each other in the Y direction.

In the present embodiment, as shown in FIG. 16, the semiconductor substrate region 200S extends in the X direction over a region corresponding to the plurality of transistor groups TG arranged in the X direction. Here, for example, in the example described with reference to FIG. 14, the plurality of word line switches WLSW (2L) arranged in the X direction and the plurality of word line switches WLSW (3L) arranged in the X direction share one of the regions of the semiconductor substrate region 200S divided by the insulating member DTI and the insulating member STI. Here, as described above, the plurality of word line switches WLSW (2L) arranged in the X direction are electrically connected to the plurality of conductive layers 110 in the memory block BLK (1). In addition, the plurality of word line switches WLSW (3L) arranged in the X direction are electrically connected to the plurality of conductive layers 110 in the memory block BLK (4). In this way, half of all the word line switches WLSW corresponding to one memory block BLK and half of all the word line switches WLSW corresponding to the other memory block BLK share one of the regions of the semiconductor substrate region 200S divided by the insulating member DTI and the insulating member STI. The substrate voltages of the plurality of word line switches WLSW are common to each other.

Meanwhile, as shown in FIG. 17, the semiconductor substrate region 200S is divided in the Y direction for each region corresponding to the plurality of transistor groups TG arranged in the Y direction. Here, for example, in the example described with reference to FIG. 14, the plurality of word line switches WLSW (1L) arranged in the X direction and the plurality of word line switches WLSW (2L) arranged in the X direction are divided by the insulating member DTI and the insulating member STI. As described above, two word line switches WLSW corresponding to one transistor group TG and two word line switches WLSW corresponding to another transistor group TG having a position different from that of the one transistor group TG in the Y direction do not share the region divided by the insulating member DTI and the insulating member STI. The substrate voltage of two word line switches WLSW corresponding to one transistor group TG and the substrate voltage of two word line switches WLSW corresponding to another transistor group TG having a position different from that of the one transistor group TG in the Y direction can be controlled independently of each other.

### Manufacturing Method

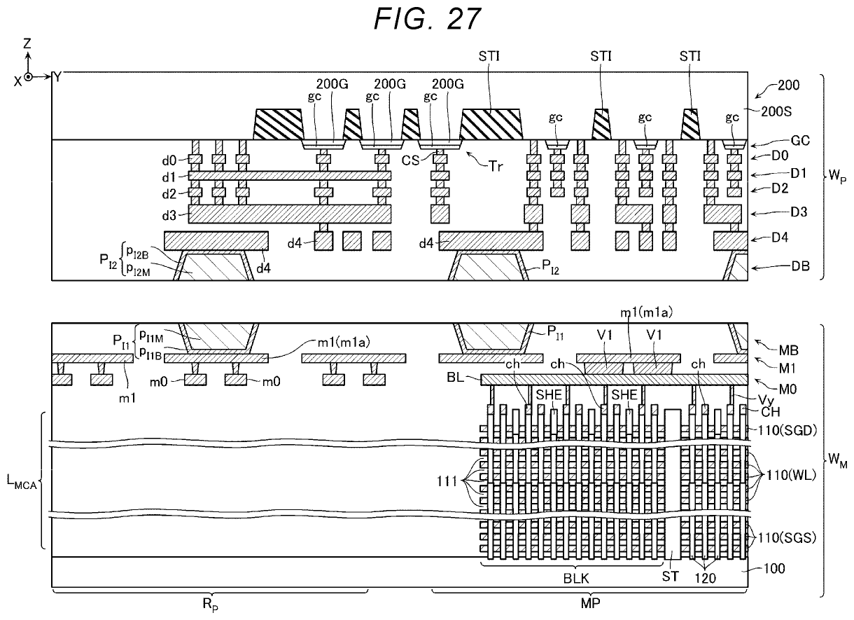

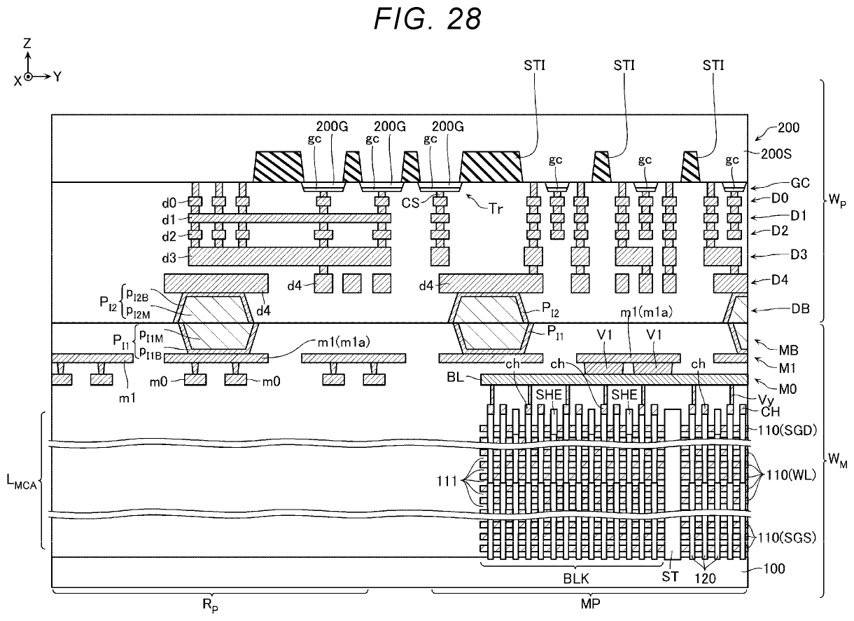

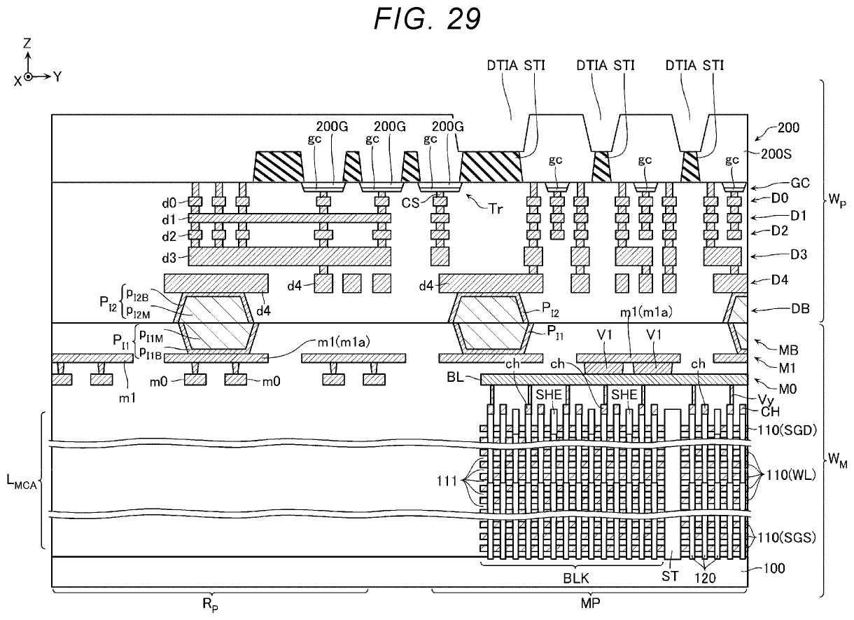

Next, a manufacturing method of the semiconductor storage device according to the first embodiment will be described with reference to FIGS. 19 to 35. FIGS. 19 to 26 are schematic cross-sectional views illustrating a manufacturing method of a CMOS portion of a chip C_{P}. FIGS. 27 and 28 are schematic cross-sectional views illustrating a manufacturing method of bonding the wafers W_{M} and W_{P}. FIGS. 29 to 35 are schematic cross-sectional views illustrating a manufacturing method of the semiconductor substrate 200 portion of the chip C_{P}. FIGS. 19 to 35 show cross sections corresponding to FIG. 7.

### Manufacturing Method of CMOS Portion of Chip C_{P}

Hereinafter, the manufacturing method of the CMOS portion of the chip C_{P}, that is, the wafer W_{P} will be described. First, as shown in FIG. 19, the insulating layer 200G is formed on the front surface of the semiconductor substrate 200. This step is performed by, for example, thermal oxidation or the like. In addition, a conductive layer gcA containing polysilicon or the like is formed on the front surface of the insulating layer 200G. This step is performed by, for example, CVD.

Next, for example, as shown in FIG. 20, an opening STIA is formed at a position corresponding to the insulating member STI described with reference to FIG. 7. The opening STIA extends in the Z direction and the X direction or the Y direction, penetrates the conductive layer gcA and the insulating layer 200G, and divides a part of the front surface of the semiconductor substrate 200. This step is performed by, for example, a method such as reactive ion etching (RIE).

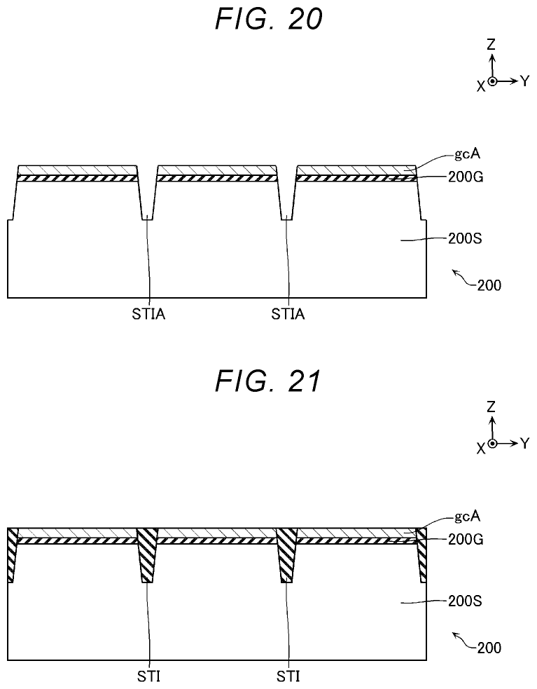

Next, an insulating layer is formed on the semiconductor substrate 200. This step is performed by, for example, chemical vapor deposition (CVD). In this step, the opening STIA is embedded in the insulating layer. Then, a part of the formed insulating layer is removed to form a plurality of the insulating members STI, for example, as shown in FIG. 21. The step of removing the part of the formed insulating layer is performed by, for example, a method such as chemical mechanical polishing (CMP).

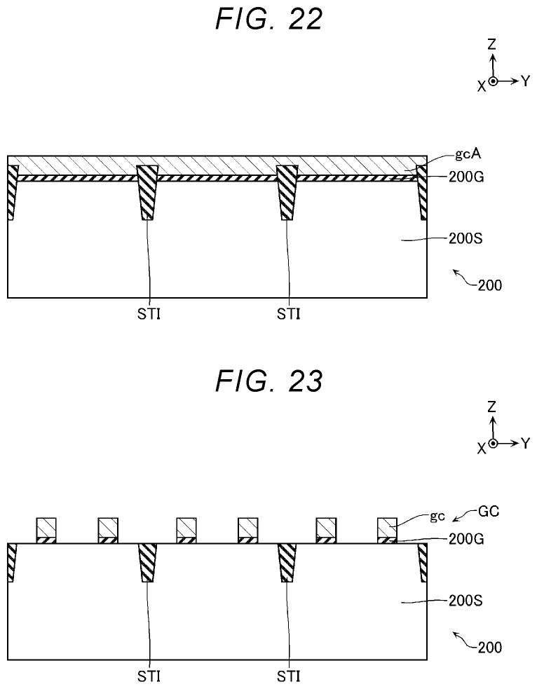

Next, for example, as shown in FIG. 22, the conductive layer gcA including tungsten (W) or the like is formed on the front surface of the conductive layer gcA. This step is performed by, for example, CVD.

Next, for example, as shown in FIG. 23, a part of the conductive layer gcA and a part of the insulating layer 200G are removed to expose the front surface of the semiconductor substrate 200, and a plurality of electrodes gc are formed. This step is performed, for example, by RIE.

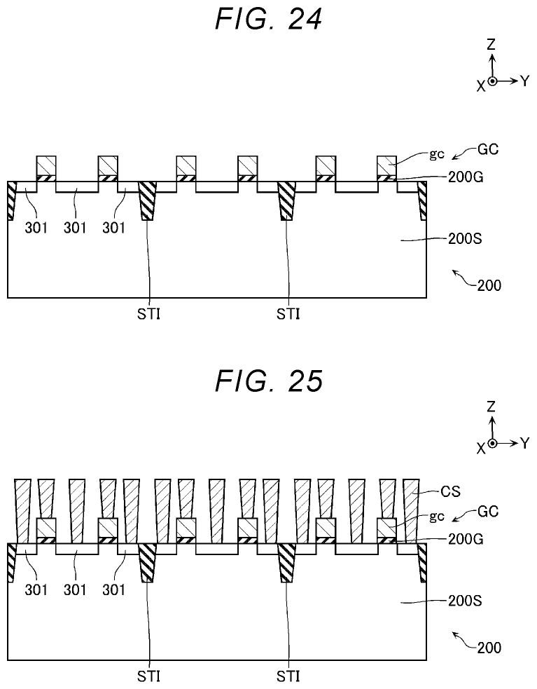

Next, for example, as shown in FIG. 24, the N-type impurities such as phosphorus (P) is implanted into the exposed front surface of the semiconductor substrate 200 to form the semiconductor region 301. This step is performed by, for example, ion implantation or the like.

Next, for example, as shown in FIG. 25, the via contact electrode CS is formed by a damascene process.

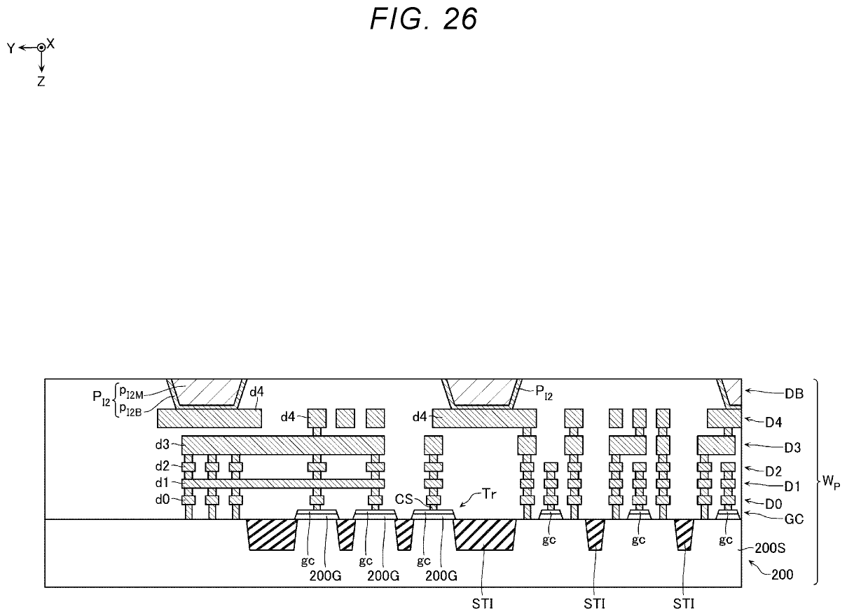

Thereafter, the wiring layers D2, D3, D4, and DB described with reference to FIG. 7 are formed by a damascene process. In the semiconductor substrate region 200S connected to the body contact region 302 shown in FIG. 15, N-type impurities such as phosphorus (P) may be implanted from the exposed rear surface of the semiconductor substrate 200 by, for example, plasma doping (PD). For example, by using a step in which a process treatment at a low temperature is possible, such as plasma doping (PD), the influence on the peripheral structure can be reduced. In this manner, for example, as shown in FIG. 26, the wafer W_{P} corresponding to the chip C_{P} is manufactured.

Step after Bonding of Wafers W_{P} and W_{M}

As shown in FIG. 27, the wafer W_{M} corresponding to the chip C_{M} is manufactured. In addition, the wafer W_{P} and the wafer W_{M} are disposed such that the wafer W_{P} front surface side and the wafer W_{M} front surface side face each other.

Next, as shown in FIG. 28, the bonding electrode P_{I2} and the bonding electrode P_{I1} are bonded to each other, and two wafers W_{M} and W_{P} are bonded to each other. This bonding step is performed by, for example, a direct bonding method to the bonding electrode.

### Manufacturing Method of Semiconductor Substrate 200 Portion of Chip C_{P}

Next, for example, as shown in FIG. 29, the opening DTIA is formed at a position corresponding to the insulating member DTI described with reference to FIG. 7. The opening DTIA extends in the Z direction and the X direction or the Y direction, penetrates the semiconductor substrate 200, and exposes the upper end of the insulating member STI. This step is performed by, for example, a method such as RIE.

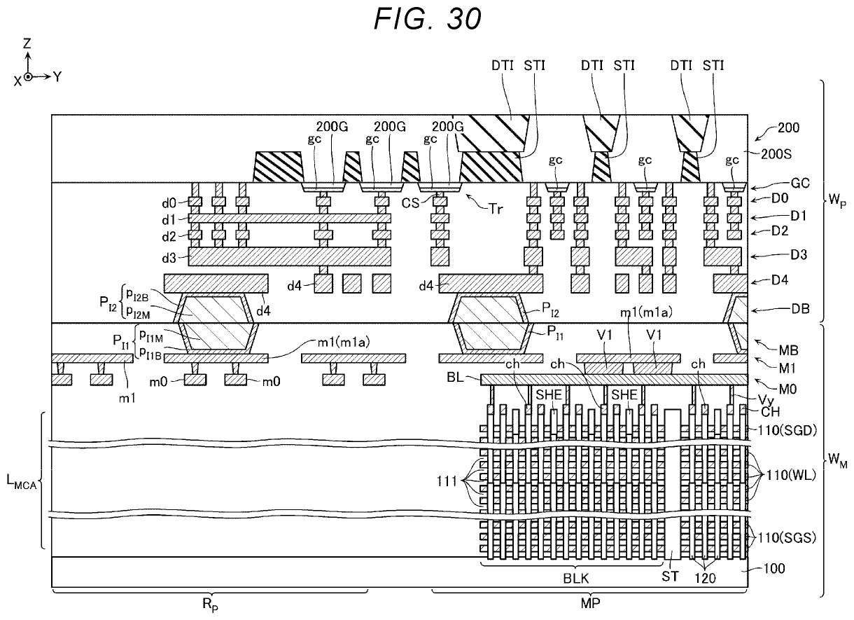

Next, an insulating layer is formed on the semiconductor substrate 200. This step is performed by, for example, CVD. In this step, the opening DTIA is embedded in the insulating layer. Then, a part of the formed insulating layer is removed to form a plurality of the insulating members DTI, for example, as shown in FIG. 30. The step of removing a part of the formed insulating layer is performed by, for example, a method such as CMP.

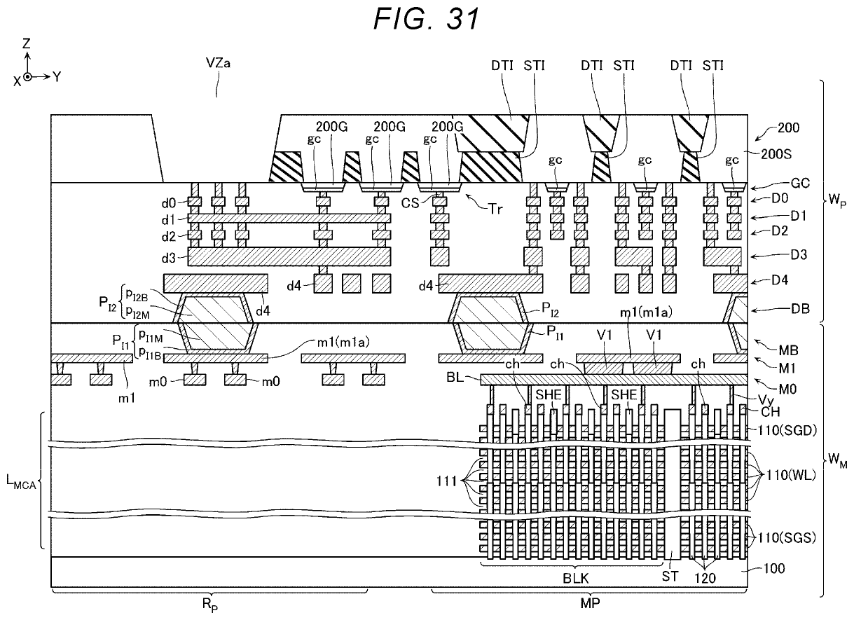

Next, for example, as shown in FIG. 31, an opening VZa is formed at a position corresponding to the opening VZ of the semiconductor substrate 200 described with reference to FIG. 7. The opening VZa extends in the Z direction and the X direction or the Y direction, penetrates the semiconductor substrate 200, and exposes the upper ends of the plurality of via contact electrodes CS. This step is performed by, for example, a method such as RIE.

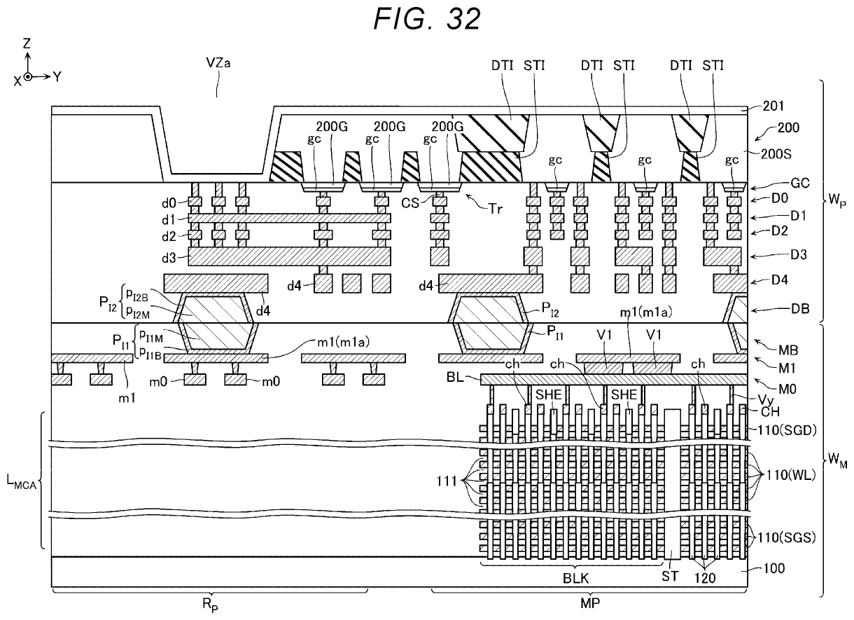

Next, for example, as shown in FIG. 32, the insulating layer 201 made of silicon oxide or the like is formed on the bottom surface and the inner peripheral surface of the opening VZa, and the upper surface of the semiconductor substrate 200. This step is performed by, for example, CVD.

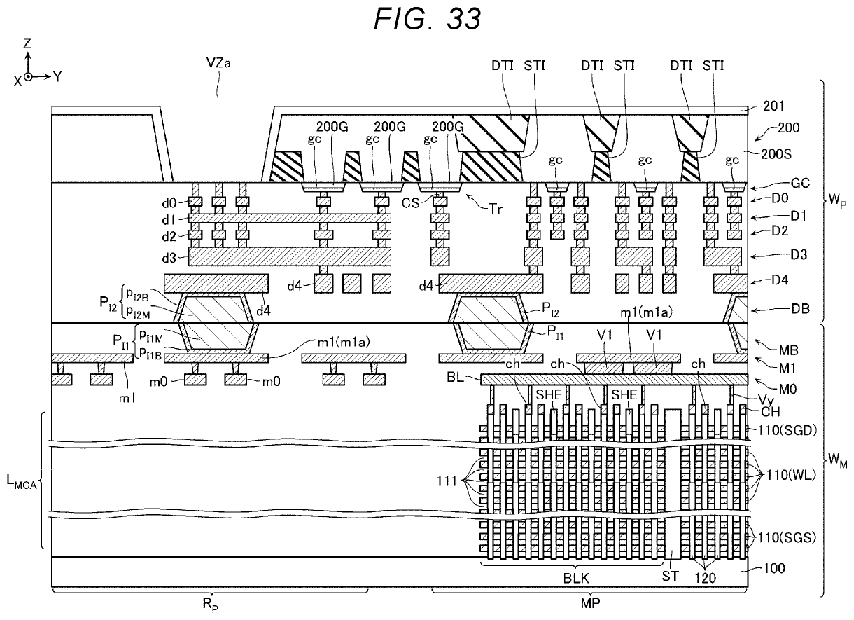

Next, for example, as shown in FIG. 33, the insulating layer 201 on the bottom surface of the opening VZa is removed to expose the upper ends of the plurality of via contact electrodes CS. This step is performed by, for example, a method such as etching back by RIE.

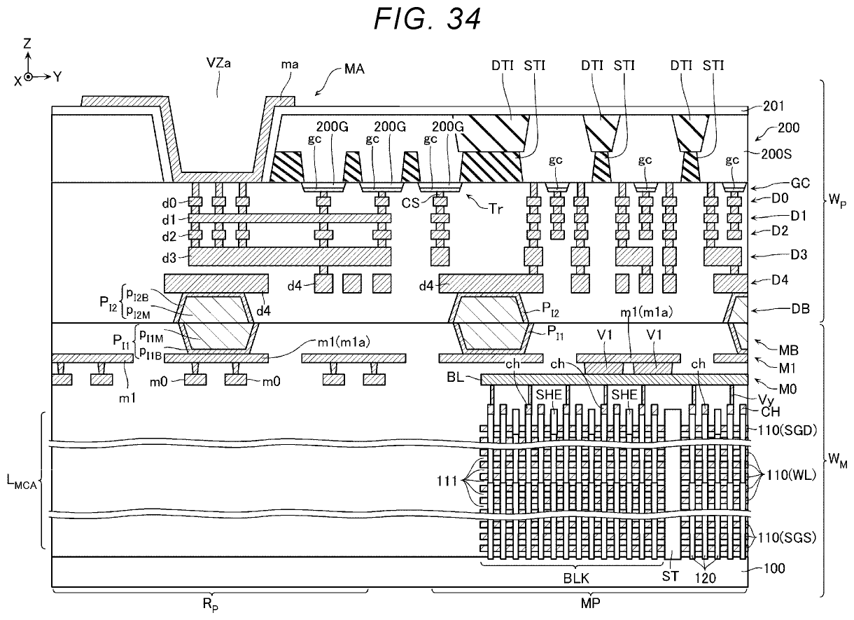

Next, for example, as shown in FIG. 34, the rear surface wiring MZ is formed on the bottom surface and the inner peripheral surface of the opening VZa, and the peripheral portion of the opening VZa. This step is performed by, for example, forming a film by CVD and forming the wiring by etching.

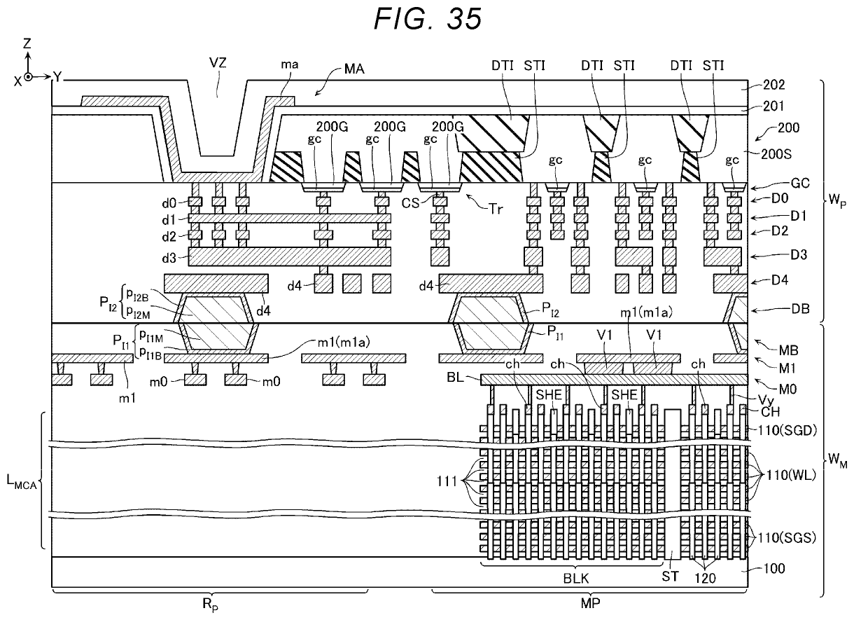

Next, for example, as shown in FIG. 35, the insulating layer 202 is formed on the upper surface of the structure shown in FIG. 34, and an opening is formed in the region VZ of the insulating layer 202. This step is performed by, for example, methods such as CVD and RIE.

By using such a rear surface processing, the semiconductor substrate 200 portion of the chip C_{P} is manufactured.

### Comparative Example

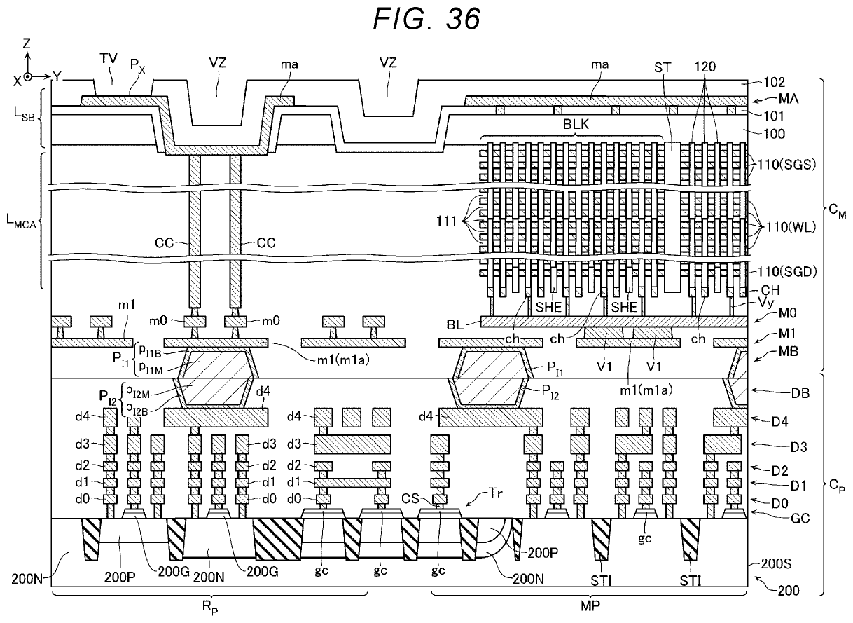

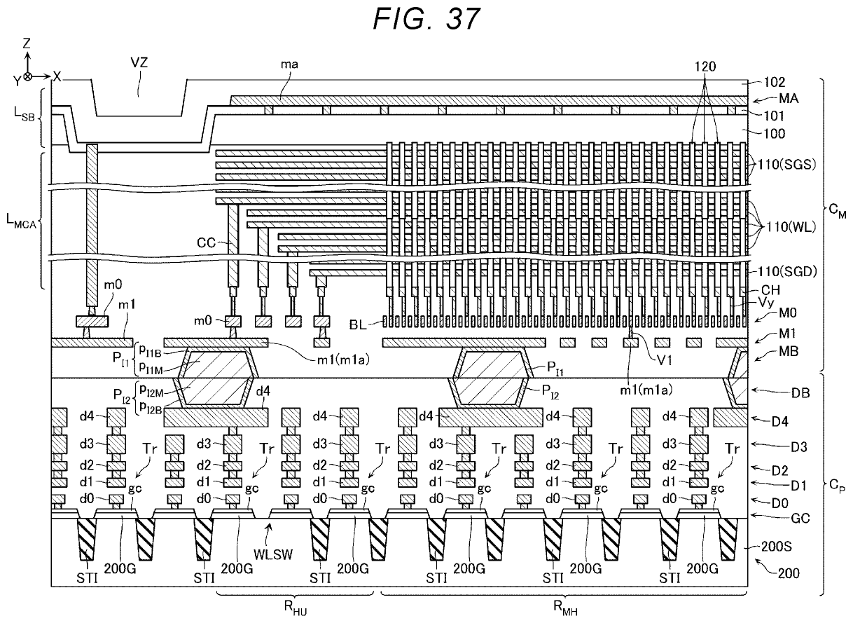

Next, a semiconductor storage device according to a comparative example will be described with reference to FIGS. 36 and 37. FIGS. 36 and 37 are schematic cross-sectional views showing a configuration of a part of the memory die MD according to the comparative example.

In the comparative example, the base layer L_{SB} is provided on the chip C_{M} instead of the chip C_{P}.

In addition, the semiconductor substrate 200 according to the comparative example is not provided with the insulating member DTI.

As described with reference to FIG. 4 and the like, the word line switch WLSW is connected to each of the word lines WL. In addition, the select gate line switch SGSW is connected to each of the select gate lines SG. Here, for example, when the write operation to the memory cell MC is performed, a relatively large voltage (program voltage) may be supplied to the word line WL, and thus a transistor having a high breakdown voltage is used as the word line switch WLSW.

In addition, when the number of word lines WL increases, the number of word line switches WLSW also increases. In order to house the row control circuit RowC in the chip C_{P}, it is necessary to reduce the word line switch WLSW. However, when the word line switch WLSW is reduced, the on-resistance Rₒₙ increases. In addition, in order to reduce the row control circuit RowC, it is also conceivable to reduce the insulating member STI. In a case of the memory die MD according to the comparative example, when the insulating member STI is reduced, the channel (inversion layer) is formed in a region deeper than the insulating member STI during the use of the word line switch WLSW, and a leakage may occur between adjacent word line switches WLSW.

Therefore, it is conceivable to form an insulating member longer in the Z direction than the insulating member STI without changing the width of the insulating member STI in the X direction (or Y direction). In this case, a step is required to process a groove deeper than the groove serving as the insulating member STI in the Z direction of the semiconductor substrate 200 and to fill the processed deep groove with the insulating film without voids. The difficulty of this processing is high, and the manufacturing cost may increase. For example, when the insulating member STI is longer in the Z direction, the processed groove has a tapered shape in which the diameter becomes narrower at a deeper position. Therefore, it is difficult to increase the length of the insulating member STI in the Z direction without changing the width of the insulating member STI in the X direction (or Y direction).

### Effect of Semiconductor Storage Device According to First Embodiment

In the semiconductor storage device according to the first embodiment, for example, as described with reference to FIG. 15 and the like, the insulating member DTI is formed at the position overlapping a part of the insulating member STI provided between the word line switches WLSW when viewed in the Z direction. According to such a configuration, even when the word line switch WLSW is reduced, the insulating region (insulating member STI or DTI) longer in the Z direction than the insulating member STI can be formed, so that the occurrence of a leakage between the adjacent word line switches WLSW can be reduced. For example, even when the program voltage is supplied to the word line switch WLSW in the write operation, the occurrence of a leakage between the adjacent word line switches WLSW can be reduced.

In addition, in the present embodiment, for example, as described with reference to FIGS. 15 to 18, the insulating member DTI is formed at the position of a part of the insulating member STI, instead of the entire insulating member STI provided between the word line switches WLSW. In such a configuration, in a region where the semiconductor substrate region 200S is not divided by the insulating member DTI, the channel region between the word line switches WLSW is continuous. Therefore, the substrate voltage of the word line switch WLSW can be suitably controlled by providing the body contact region 302 for each of the plurality of regions of the semiconductor substrate region 200S divided by the insulating member DTI.

In addition, for example, when a negative voltage is supplied to the source electrode of the word line switch WLSW and the voltage in the body contact region 302 is about the ground voltage VSS, the source electrode of the word line switch WLSW and the voltage in the body contact region 302 are in a positive bias relationship, and the memory die MD may be destroyed. In order to prevent this, it is conceivable to supply a negative voltage to the semiconductor substrate region 200S. When the semiconductor substrate region 200S is continuous over the entire memory die MD and a negative voltage is supplied to the entire semiconductor substrate region 200S, the power consumption may increase or the operation speed may decrease. In this respect, in the present embodiment, since the semiconductor substrate region 200S is divided into a plurality of regions by the insulating members STI and DTI, it is possible to selectively supply a negative voltage to a part of the semiconductor substrate region 200S during the operation of the memory die MD.

Further, the insulating member STI and the insulating member DTI can be formed by separate processes, and the insulating member DTI can be formed by rear surface processing. With such a configuration, the insulating member STI can be easily formed as compared with a case where the insulating member STI is formed long in the Z direction. In addition, since the width of the insulating member DTI in the X direction (or the Y direction) can be larger than the width of the insulating member STI in the X direction (or the Y direction), the insulating member DTI can be easily formed from the rear surface of the semiconductor substrate 200 to the position of the insulating member STI. That is, since the processing dimension for processing the insulating region for electrically separating the adjacent word line switches WLSW can be relaxed, the manufacturing cost can be reduced.

### Second Embodiment

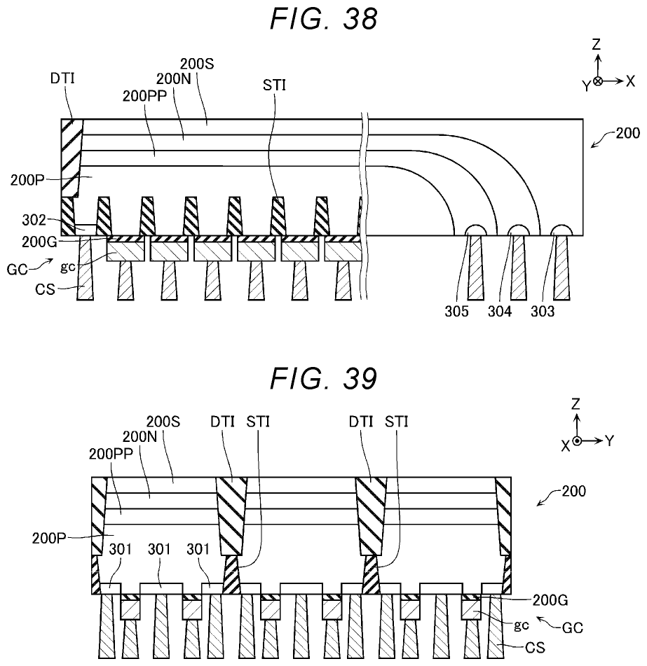

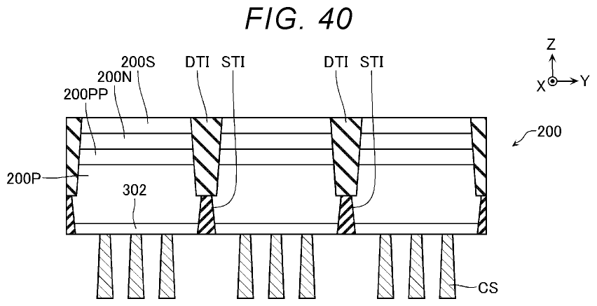

FIGS. 38, 39 and 40 are schematic cross-sectional views showing a partial configuration of the semiconductor storage device according to the second embodiment. FIGS. 38 to 40 correspond to FIGS. 16 to 18, and the same components as in FIGS. 16, 17, and 18 are denoted by the same reference signs, and redundant description will not be repeated. FIGS. 38, 39, and 40 are views illustrating a configuration of a part of the chip C_{P}. FIG. 38 is a view cut along the line A-A′ shown in FIG. 15 and viewed in a direction of an arrow. FIG. 39 is a view cut along the line B-B′ shown in FIG. 15 and viewed in a direction of an arrow. FIG. 40 is a view cut along the line C-C′ shown in FIG. 15 and viewed in a direction of an arrow.

The semiconductor storage device according to the second embodiment is different from the semiconductor storage device according to the first embodiment in that, as shown in FIGS. 38, 39, and 40, the N-type well region 200N (well) and P-type well regions 200PP and 200P (well) are provided in the semiconductor substrate region 200S in the row control circuit region R_{RC}.

The semiconductor substrate 200, as described above, contains P-type silicon (Si) containing P-type impurities such as boron (B), for example. The N-type well region 200N contains, for example, N-type impurities such as phosphorus (P). The P-type well region 200PP is provided at a position overlapping the N-type well region 200N when viewed in the Z direction, and contains P-type impurities such as boron (B). The P-type well region 200P is provided at a position overlapping the P-type well region 200PP when viewed in the Z direction, and contains P-type impurities such as boron (B). The impurity concentration of the P-type well region 200PP is higher than the impurity concentration of the P-type well region 200P. The plurality of word line switches WLSW (transistors) are provided in the P-type well region 200P.

According to such a configuration, the via contact electrode CS functioning as the front surface contact of the chip C_{P} and the N-type well region 200N and the P-type well region 200PP are provided in the semiconductor substrate region 200S. Accordingly, the defects in the rear surface processing (the defects generated in the semiconductor substrate 200 portion of the chip C_{P} during the manufacturing) and the influence of the rear surface voltage of the chip C_{P} can be reduced.

In the present embodiment, the body contact region 302 is in contact with the P-type well region 200P, not with the semiconductor substrate region 200S.

In addition, FIG. 38 shows body contact regions 303, 304, and 305. Via contact electrodes CS (contacts) that function as the front surface contacts of the chip C_{P} are provided on the lower surfaces of the body contact regions 303, 304, and 305.

The body contact region 303 is provided on the lower surface of the semiconductor substrate 200 and is in contact with the semiconductor substrate region 200S. The body contact region 303 is a contact impurity region and includes P-type impurities such as boron (B), that is, the same conductivity-type impurities as the semiconductor substrate region 200S. The impurity concentration of the body contact region 303 is higher than the impurity concentration of the semiconductor substrate region 200S.

The body contact region 304 is provided on the lower surface of the semiconductor substrate 200 and is in contact with the N-type well region 200N. The body contact region 304 is a contact impurity region and includes N-type impurities such as phosphorus (P), that is, the same conductivity-type impurity as the N-type well region 200N. The impurity concentration of the body contact region 304 is higher than the impurity concentration of the N-type well region 200N.

The body contact region 305 is provided on the lower surface of the semiconductor substrate 200 and is in contact with the P-type well region 200PP. The body contact region 305 is a contact impurity region and includes P-type impurities such as boron (B), that is, the same conductivity-type impurities as the P-type well region 200PP. The impurity concentration of the body contact region 305 is higher than the impurity concentration of the P-type well region 200PP.

The semiconductor substrate region 200S, the N-type well region 200N, and the P-type well region 200PP are connected to the via contact electrodes CS via the body contact regions 303, 304, and 305 provided in the semiconductor substrate 200, respectively.

### Third Embodiment

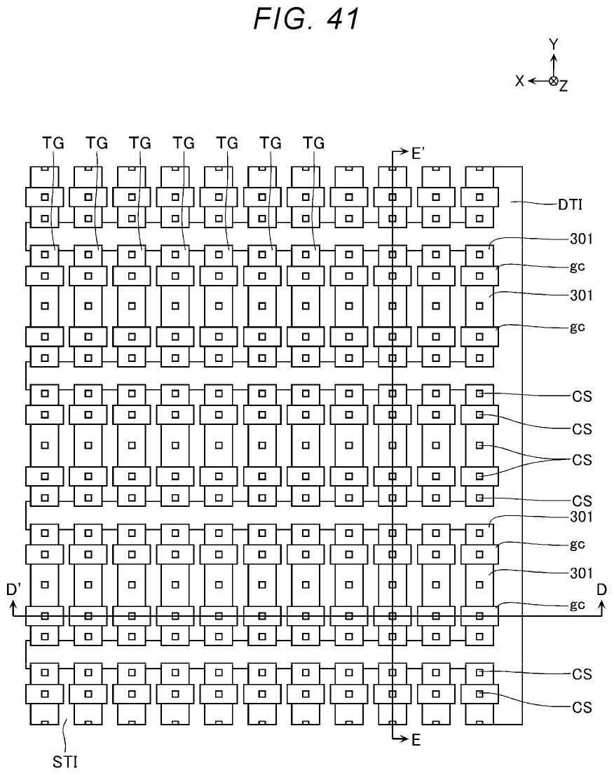

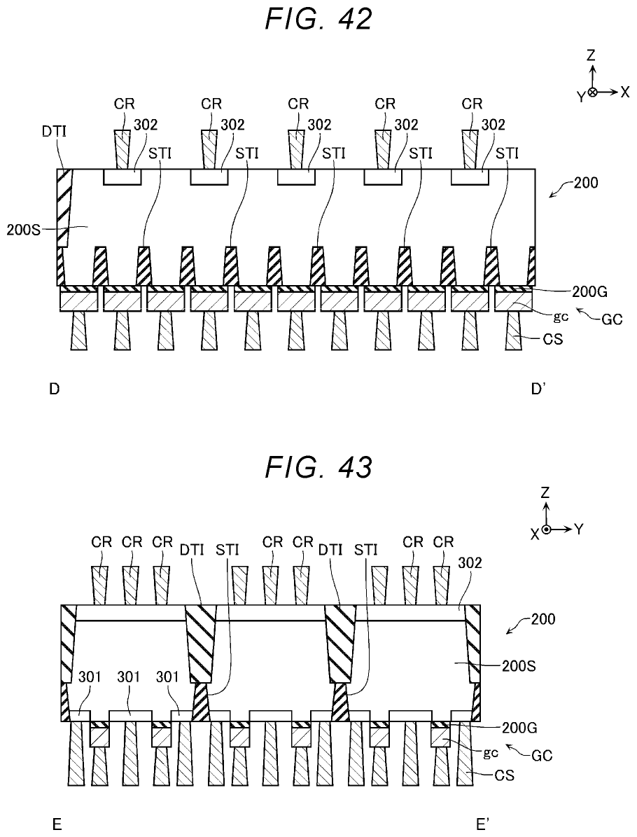

FIG. 41 is a schematic bottom view showing a configuration of a part of a semiconductor storage device according to a third embodiment. FIGS. 42 and 43 are schematic cross-sectional views showing a partial configuration of the semiconductor storage device according to the third embodiment. FIGS. 41, 42, and 43 correspond to FIGS. 15, 16, and 17, and the same components as in FIGS. 15, 16, and 17 are denoted by the same reference signs, and redundant description will not be repeated. FIGS. 42 and 43 are views illustrating a configuration of a part of the chip C_{P}. FIG. 42 is a view cut along the line D-D′ shown in FIG. 41 and viewed in a direction of an arrow. FIG. 43 is a view cut along the line E-E′ shown in FIG. 41 and viewed in a direction of an arrow.

The semiconductor storage device according to the third embodiment is basically configured in the similar manner to the semiconductor storage device according to the first embodiment. However, in the configuration of the first embodiment, the body contact region 302 is provided on the lower surface of the semiconductor substrate 200 (FIGS. 15 and 16). Meanwhile, in the configuration of the third embodiment, as shown in FIGS. 42 and 43, the body contact region 302 is provided on the upper surface of the semiconductor substrate 200. In addition, a via contact electrode CR that functions as a rear surface contact of the chip C_{P} is provided on the upper surface of the body contact region 302. The via contact electrode CR extends in the Z direction and is connected to the body contact region 302 of the semiconductor substrate 200 at the lower end. The via contact electrode CR may include, for example, a stacked film of a barrier conductive film made of titanium nitride (TiN) or the like and a metal film made of tungsten (W) or the like.

According to such a configuration, as compared with the configuration of the first embodiment, it is possible to reduce the body contact region provided on one end side of the transistor group TG arranged in the X direction.

### Fourth Embodiment

In the first to third embodiments, the arrangement pattern of the insulating member DTI is described. The configuration described above is merely an example, and the specific arrangement pattern of the insulating member DTI can be appropriately adjusted. Hereinafter, as the fourth embodiment, another arrangement pattern of the insulating member DTI will be described.

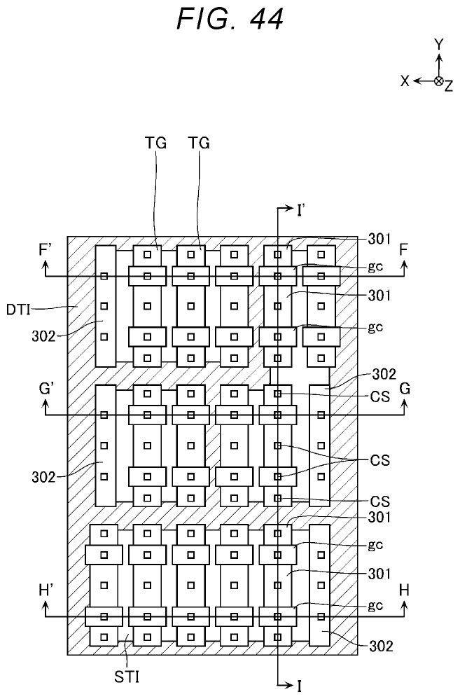

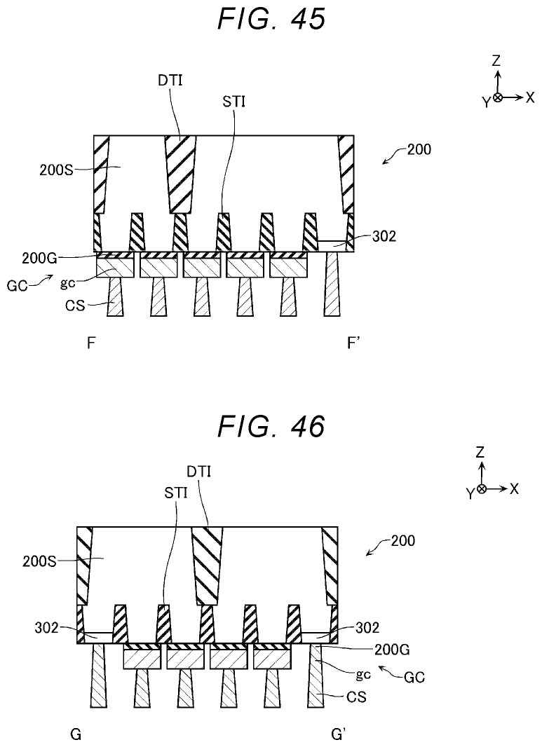

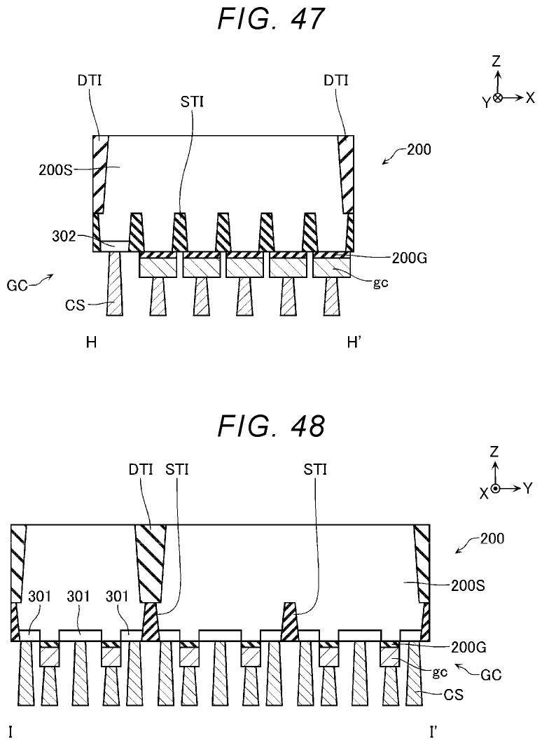

FIG. 44 is a schematic plan view showing a configuration of a part of a semiconductor storage device according to the fourth embodiment. FIGS. 45, 46, 47, and 48 are schematic cross-sectional views showing a partial configuration of the semiconductor storage device according to the fourth embodiment. In FIGS. 45, 46, 47, and 48, the same components as in FIGS. 15, 16, and 17 are denoted by the same reference signs, and redundant description will not be repeated. FIGS. 44 to 48 are views illustrating a configuration of a part of the chip C_{P}. FIG. 45 is a view cut along the line F-F′ shown in FIG. 44 and viewed in a direction of an arrow. FIG. 46 is a view cut along the line G-G′ shown in FIG. 44 and viewed in a direction of an arrow. FIG. 47 is a view cut along the line H-H′ shown in FIG. 44 and viewed in a direction of an arrow. FIG. 48 is a view cut along the line G-G′ shown in FIG. 44 and viewed in a direction of an arrow.

The semiconductor storage device according to the fourth embodiment is basically configured in the similar manner to the semiconductor storage device according to the first embodiment.

In the configuration of the first embodiment, for example, as described with reference to FIG. 15, the plurality of transistor groups TG arranged in the X direction share one of the regions of the semiconductor substrate region 200S divided by the insulating member DTI and the insulating member STI. However, for example, as shown in FIGS. 44 to 46, the plurality of transistor groups TG arranged in the X direction may not share the regions of the semiconductor substrate region 200S divided by the insulating member DTI and the insulating member STI. FIG. 45 shows an example of five word line switches WLSW arranged in the X direction. In the example of FIG. 45, two of the five word line switches WLSW share one of the regions of the semiconductor substrate region 200S divided by the insulating member DTI and the insulating member STI. In addition, the remaining three share the other one of the regions of the semiconductor substrate region 200S divided by the insulating member DTI and the insulating member STI. However, these two regions are divided from each other by the insulating member DTI and the insulating member STI.

In addition, in the configuration of the first embodiment, for example, as described with reference to FIG. 15, two transistor groups TG having different positions in the Y direction do not share the region divided by the insulating member DTI and the insulating member STI. However, for example, as shown in FIGS. 44 and 48, two transistor groups TG having different positions in the Y direction may share one of the regions of the semiconductor substrate region 200S divided by the insulating member DTI and the insulating member STI. FIG. 48 shows three transistor groups TG arranged in the Y direction. In the example of FIG. 48, two of the three transistor groups TG share one of the regions of the semiconductor substrate region 200S divided by the insulating member DTI and the insulating member STI. Meanwhile, the remaining one is divided from the other two by the insulating member DTI and the insulating member STI.

In the examples of FIGS. 44 to 48, the body contact region 302 is provided in the plurality of regions of the semiconductor substrate region 200S divided by the insulating member DTI and the insulating member STI.

### OTHER EMBODIMENTS

Hitherto, the semiconductor storage device according to the first to fourth embodiments is described. The above-described configuration is merely an example, and a specific configuration can be appropriately adjusted.

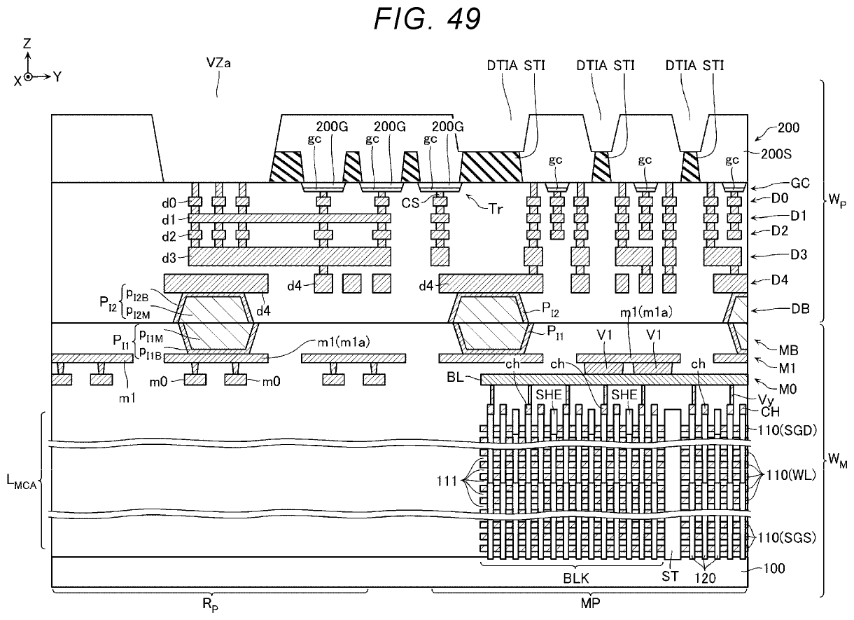

FIG. 49 is a schematic cross-sectional view illustrating the manufacturing method of the semiconductor substrate 200 portion of the chip C_{P} according to the other embodiments.

In the manufacturing method of the semiconductor substrate 200 portion of the chip C_{P}, an example in which the opening DTIA and the opening VZa are formed in different steps is described with reference to FIGS. 29 and 31, and the present disclosure is not limited thereto. For example, as shown in FIG. 49, the opening DTIA and the opening VZa may be formed at the same time. This step is performed by, for example, a method such as RIE as described above.

In addition, in FIGS. 7 and 8, the bonding electrode Pr and the wiring d4 are connected without the use of the via contact electrode, and may be connected via the via contact electrode.

In addition, in the above embodiments, an example of application to a NAND flash memory is described. However, the techniques described in the present specification can be applied to configurations other than the semiconductor storage device such as a three-dimensional NOR flash memory. In addition, the techniques described in the present specification can also be applied to the configuration of a semiconductor device other than the semiconductor storage device.

### OTHERS

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a first chip and a second chip that are bonded to each other,
wherein the first chip includes
a semiconductor substrate having a first surface and a second surface intersecting a first direction,
a plurality of transistors provided on the first surface of the semiconductor substrate,
a plurality of first contacts extending in the first direction and connected to the plurality of transistors, and
a plurality of first bonding electrodes electrically connected to the plurality of transistors via the plurality of first contacts,
the second chip includes
a plurality of first conductive layers arranged in the first direction,
a semiconductor column extending in the first direction and facing the plurality of first conductive layers,
a plurality of second contacts extending in the first direction and connected to the plurality of first conductive layers, and
a plurality of second bonding electrodes connected to the plurality of first conductive layers via the plurality of second contacts,
the plurality of first bonding electrodes are bonded to the plurality of second bonding electrodes,
the plurality of transistors include a first transistor and a second transistor adjacent to each other in a second direction intersecting the first direction,
the semiconductor substrate includes
a first insulating member provided between the first transistor and the second transistor and extending in the first direction from the first surface of the semiconductor substrate to a first position between the first surface and the second surface of the semiconductor substrate, and
a second insulating member provided at a position overlapping the first insulating member when viewed in the first direction and extending in the first direction from the second surface of the semiconductor substrate to the first position of the semiconductor substrate, and
a width of the second insulating member in the second direction at the second surface is larger than a width of the first insulating member in the second direction at the first surface.

2. The semiconductor storage device according to claim 1,
wherein the semiconductor substrate includes a first semiconductor region surrounded by the second insulating member at the first surface of the semiconductor substrate,
the plurality of transistors include the first transistor having a channel region provided in the first semiconductor region and a third transistor having a channel region provided in the first semiconductor region, and
the first semiconductor region is continuous from a channel region of the first transistor to a channel region of the third transistor.

3. The semiconductor storage device according to claim 2,
wherein the semiconductor substrate further includes a third insulating member provided between the first transistor and the third transistor and extending in the first direction from the first surface of the semiconductor substrate to a second position between the first surface and the second surface of the semiconductor substrate.

4. The semiconductor storage device according to claim 1,
wherein the width of the first insulating member in the second direction at the first surface is larger than a width in the second direction at the first position, and
the width of the second insulating member in the second direction at the second surface is larger than a width in the second direction at the first position.

5. The semiconductor storage device according to claim 1,
wherein a width of the second insulating member in the second direction at the first position is larger than a width of the first insulating member in the second direction at the first position.

6. The semiconductor storage device according to claim 1,
wherein the plurality of transistors includes a first group of transistors that are arranged in a third direction intersecting the first direction and the second direction, and a second group of transistors that are arranged in the third direction and spaced apart from the first group in the second direction, and
the second insulating member extends in the third direction between the first group of transistors and the second group of transistors.

7. The semiconductor storage device according to claim 6,
wherein the plurality of first conductive layers extend in the third direction.

8. The semiconductor storage device according to claim 1,
wherein the first chip includes
a third contact extending in the first direction from the first surface of the semiconductor substrate,
the semiconductor substrate includes
a first region containing a first conductivity-type impurity, and
a second region in contact with the third contact and containing the first conductivity-type impurity, and
a concentration of the first conductivity-type impurity in the second region is higher than a concentration of the first conductivity-type impurity in the first region.

9. The semiconductor storage device according to claim 1,
wherein the first chip includes a fourth contact extending in the first direction from the second surface of the semiconductor substrate.

10. The semiconductor storage device according to claim 9,
wherein the semiconductor substrate includes
a first region containing a first conductivity-type impurity, and
a third region in contact with the fourth contact and containing the first conductivity-type impurity, and
a concentration of the first conductivity-type impurity in the third region is higher than a concentration of the first conductivity-type impurity in the first region.

11. The semiconductor storage device according to claim 1,
wherein the semiconductor substrate contains a first conductivity-type impurity and includes
a first well containing a second conductivity-type impurity different from the first conductivity-type, and
a second well provided at a position overlapping the first well when viewed in the first direction and containing the first conductivity-type impurity, and
the plurality of transistors are provided in the second well.

12. The semiconductor storage device according to claim 11,
wherein the first chip includes
a fifth contact extending in the first direction from the first surface of the semiconductor substrate, and
a sixth contact extending in the first direction from the first surface of the semiconductor substrate,
the semiconductor substrate includes
a fourth region formed in the first well at the first surface, in contact with the fifth contact, and containing the second conductive type impurity, and
a fifth region formed in the second well at the first surface, in contact with the sixth contact, and containing the first conductive type impurity,
a concentration of the second conductivity-type impurity in the fourth region is higher than a concentration of the second conductivity-type impurity in the first well, and
a concentration of the first conductivity-type impurity in the fifth region is higher than a concentration of the first conductivity-type impurity in the second well.

13. A semiconductor device comprising:
a semiconductor substrate having a first surface and a second surface intersecting a first direction; and
a plurality of transistors provided on the first surface of the semiconductor substrate,
wherein the plurality of transistors include a first transistor and a second transistor adjacent to each other in a second direction intersecting the first direction,
the semiconductor substrate includes
a first insulating member provided between the first transistor and the second transistor and extending in the first direction from the first surface of the semiconductor substrate to a first position between the first surface and the second surface of the semiconductor substrate, and
a second insulating member provided at a position overlapping the first insulating member when viewed in the first direction and extending in the first direction from the second surface of the semiconductor substrate to the first position of the semiconductor substrate, and
a width of the second insulating member in the second direction at the second surface is larger than a width of the first insulating member in the second direction at the first surface.

14. The semiconductor device according to claim 13,
wherein the semiconductor substrate includes a first semiconductor region surrounded by the second insulating member at the first surface of the semiconductor substrate,
the plurality of transistors include the first transistor having a channel region provided in the first semiconductor region and a third transistor having a channel region provided in the first semiconductor region, and
the first semiconductor region is continuous from a channel region of the first transistor to a channel region of the third transistor.

15. The semiconductor device according to claim 14,
wherein the semiconductor substrate further includes a third insulating member provided between the first transistor and the third transistor and extending in the first direction from the first surface of the semiconductor substrate to a second position between the first surface and the second surface of the semiconductor substrate.

16. The semiconductor device according to claim 13,
wherein the width of the first insulating member in the second direction at the first surface is larger than a width in the second direction at the first position, and
the width of the second insulating member in the second direction at the second surface is larger than a width in the second direction at the first position.

17. The semiconductor device according to claim 13,
wherein a width of the second insulating member in the second direction at the first position is larger than a width of the first insulating member in the second direction at the first position.

18. The semiconductor device according to claim 13, further comprising:
a first via contact electrode that extends in the first direction from the first surface of the semiconductor substrate,
wherein the semiconductor substrate includes
a first region containing a first conductivity-type impurity, and
a second region in contact with the first via contact electrode and containing the first conductivity-type impurity, and
a concentration of the first conductivity-type impurity in the second region is higher than a concentration of the first conductivity-type impurity in the first region.

19. The semiconductor device according to claim 13, further comprising:
a second via contact electrode that extends in the first direction from the second surface of the semiconductor substrate.

20. The semiconductor device according to claim 19,
wherein the semiconductor substrate includes
a first region containing a first conductivity-type impurity, and
a third region in contact with the second via contact electrode and containing the first conductivity-type impurity, and
a concentration of the first conductivity-type impurity in the third region is higher than a concentration of the first conductivity-type impurity in the first region.
